(19) United States
(12) Patent Application Publication
(10) Pub. No.: US 2025/0163211 A1
(43) Pub. Date: May 22, 2025

(54) MIXED SOLID-STATE IONIC-ELECTRONIC POLYMER CONDUCTORS FOR ELECTROCHEMICAL DEVICES

(71) Applicant: THE REGENTS OF THE UNIVERSITY OF CALIFORNIA, Oakland, CA (US)

(72) Inventors: Gao LIU, Piedmont, CA (US); Tianyu ZHU, El Cerrito, CA (US)

(21) Appl. No.: 19/033,287

(22) Filed: Jan. 21, 2025

Related U.S. Application Data
(63) Continuation of application No. PCT/US2023/028482, filed on Jul. 24, 2023.
(60) Provisional application No. 63/369,182, filed on Jul. 22, 2022.

(51) Int. Cl. C08G 61/02; H01M 4/66

(52) U.S. Cl. CPC C08G 61/02; H01M 4/667; C08G 2150/00

(57) ABSTRACT

The present invention provides for a composition comprising: a solvent, optionally one or more active material and/or additive particles, and the conductive polymer of the present invention. In some embodiments, the composition is a slurry. The present invention also provides for a device comprising a current collector applied or coated with the composition of the present invention, and a method to convert a conductive polymer into a final form comprising: (a) providing a device of the present invention comprising a current collector applied or coated with the composition of the present invention; (b) thermally or optically treating the composition such that the conductive polymer is converted into a final form.

### CROSS-REFERENCE TO RELATED APPLICATIONS

This application claims priority as a continuation application to PCT International Patent Application No. PCT/US2023/028482, filed on Jul. 24, 2023, which claims priority to U.S. Provisional Patent Application Ser. No. 63/369,182, filed on Jul. 22, 2022, both of which are hereby incorporated by reference.

### STATEMENT OF GOVERNMENTAL SUPPORT

The invention was made with government support under Contract Nos. DE-AC02-05CH11231 awarded by the U.S. Department of Energy. The government has certain rights in the invention.

### FIELD OF THE INVENTION

The present invention is in the field of electrochemical devices.

### BACKGROUND OF THE INVENTION

With the discovery of electrically conductive organics in the 1930's and the continuous exploration of conductive macromolecules since the 1980s, the field of intrinsically conductive polymers has seen tremendous growth in both molecular designs and their usage as functional materials. In terms of practical applications, conductive polymers have been widely utilized ranging from antistatic coatings, to sensors and to energy materials, such as light emitting materials in polymer light emitting diodes (PLED), and charge transport and energy harvesting materials in plastic photovoltaics (PV). In nearly all cases, low-cost and solvent processability are the major driving force for the utilization of the conductive polymers. The improved electrical conduction properties of the polymers are achieved by modification of primary structures through bottom-up polymer design and synthesis, such as engineering electron-donating and electron-withdrawing groups to adjust the band gap to achieve either desired emission (or absorption), or to optimize molecular orbitals (HOMO and LUMO) to match energy levels in adjacent optoelectronic components to maximize efficacy. As an alternative to complex primary structures, we consider a new paradigm of forming well-organized three-dimensional architectures, termed as hierarchically ordered structures (HOS), to achieve the desired functionality that is unattainable with bottom-up synthetic approaches focusing only on modifying the primary molecular structure.

Charge transport (both electron and ion) phenomena in polymer materials plays a crucial role in energy storage devices and biological systems. Charge transport in polymers is typically optimized by the primary structural modification of the polymers, although the intermolecular interaction and the mesoscale morphology have a much higher impact on charge transport. For the case in lithium batteries, polymers are expected to provide surface protection, adhesion and elasticity, which has been achieved through primary structural engineering. However, limited experimental effort has been devoted to understanding and manipulating their transport behavior. Typically, poor ion transport can result in additional interfacial energy barriers and detrimental concentration gradients, limiting the efficiency and rate capability of the device. Most commonly, elastic polymers or hybrid networks based on ethylene oxide (EO) moieties when swelled by liquid electrolyte, can transport Li-ions through segmental motion or vehicular mechanism. More recently, progress has been made in designing microporous structures with solid solvation cages to promote Li-ion partition and enhance solubility-driven transport. Overall, most earlier work tends to address the transport issue by screening a diversity of primary structures. Directly manipulating the transport behavior of known molecules through engineering HOS has never been executed, and an in-depth understanding of the multiscale electron transfer and ion transport mechanisms, especially in the case of commonly used amorphous polymers, is largely missing.

### SUMMARY OF THE INVENTION

The present invention provides for a conductive polymer described herein.

The present invention provides for a composition comprising: a solvent, optionally one or more active material and/or additive particles, and the conductive polymer of the present invention. In some embodiments, the composition is a slurry.

The present invention provides for a device comprising a current collector applied or coated with the composition of the present invention. In some embodiments, the composition is dried on the current collector. In some embodiments, the dried composition is a film, such as a laminate film, such as a composite laminate film.

The present invention provides for a method to convert a conductive polymer into a final form, the method comprising: (a) providing a device of the present invention comprising a current collector applied or coated with the composition of the present invention; (b) thermally or optically treating the composition such that the conductive polymer is converted into a final form. The conductive polymer in the final form has one or more of the advantages described herein.

In some embodiments, the conductive polymer can easily dissolve in NMP solution. In some embodiments, the conductive polymer in the final form is useful as a binder and surface protection agent for a Si electrode, or a carbon, Si, Al, Li, or Sn surface.

In some embodiments, the thermally treating step comprises heating the composition. In some embodiments, the thermally treating step comprises heating the composition to a temperature ranging from about 100° C. to about 1000° C. In some embodiments, the thermally or optically treating step takes place in an oxygen free condition, or a control amount of oxygen condition. In some embodiments, the optically treating step comprises contacting or shining high-energy visible light on the composition. In some embodiments, the thermally or optically treating step results in the separating or removing of one or more R group (such as one or more of R₁-R₁₅), or side chain/functional group, from the conductive polymer. In some embodiments, the device comprises a film of the composition, used in combination with a liquid electrolyte, gel or solid-state electrolytes.

In some embodiments, the providing step comprises applying or coating the current collector with the composition of the present invention, and optionally drying the composition of the present invention so that the solvent in the composition is separated from the conductive polymer.

In some embodiments, the providing step comprises heating the composition or conductive polymer such that the conductive polymer is converted into a final form. In some embodiments, the final form of the conductive polymer forms a coating and/or protective layer. In some embodiments, the final form of the conductive polymer forms a coating and/or protective layer covering the active materials particles.

In some embodiments, the final form of the conductive polymer forms a coating and/or protective layer covering a surface of carbon, Si, Al, Li, or Sn.

In some embodiments, the applying or coating step comprises dissolving the conductive polymer in a solvent to produce the composition of the present invention.

(2) The polymers can be dissolved in a selected solvent and coated on to the active materials surface and dried and thermal treated at the selected temperature to transform into the final form to form the coating and protective layer. The coated particles can be used as battery materials. (3) The polymer can be directly coated on a flat surface such as carbon, Si, Al, Li, Sn film surface and be thermal treated to transform into the final form. (4)

In some embodiments, the device is a battery, such as a lithium battery, sodium battery, or Mg and/or Zn battery system. In some embodiments, the device is any device in need of a conductive polymer on a current collector that requires ion or electron mobility through the conductive polymer.

In some embodiments, the conductive polymer has the following chemical structure:

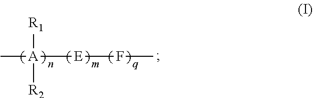

n+m+q=1, and representing the relative abundance in the polymer chain; n, m, and q can be any number between 0-1; R₁ and R₂ are an alkyl chain or oligo ethyleoxide chain or alkyloxide chain of any length between 1-10000 carbon atoms; and, R₁ and R₂ can be hydroxide terminated or carboxylic acid or carboxylate salt terminated.

In some embodiments, chemical structure (I) (also referred to as “the first generic structure”) has the following chemical structure:

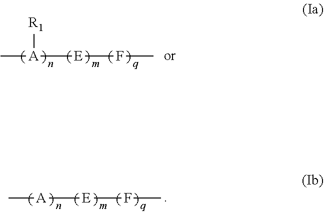

The heating or light process can lead to a partial or complete loss of R₁ and R₂ in any composition in the end form. The temperature can range from 100 to 1000° C. The thermal treatment or light process can be oxygen free or have control amount of oxygen.

In some embodiments, chemical structure (I) comprises random copolymer(s) or block copolymer(s).

In some embodiments, chemical structure (I) is transformed, from or to, when thermal treated at high temperature to lose the side chains R₁ and/or R₂.

In some embodiments, the

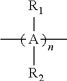

segment is one of the chemical structures described in FIG. 2.

In some embodiments, the

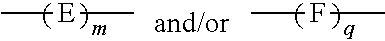

segments are independently one of the chemical structures described in FIG. 3.

In some embodiments, chemical structure (I) is described in FIG. 4. Examples of poly(9,9-dioctylfluorene-co-fluorenone-co-methylbenzoic ester) (PFM) and Si composite electrode first generic structure process and usages are described in FIG. 4. In some embodiments, PFM, or any first generic structure of the polymers, chemical transformation during thermal treatment at about 500° C. The PFM and Si can be processed into a polymer composite electrode, the pyrolysis at about 500° C. transformed the PFM polymer in the electrode.

In some embodiments, the conductive polymer has the following chemical structure: -Qₙ-Q′ₘ- (II) (also referred to as “the second generic structure”); wherein n is between 1 and 100M Dalton; R₁ and/or R₂ are independently an alkyl chain or oligo ethyleoxide chain or alkyloxide chain of any length between 1-10000 carbon atoms; and R₁ and/or R₂ can be hydroxide terminated or carboxylic acid or carboxylate salt terminated. In some embodiments, -Q′ₘ- is a covalent bond. In some embodiments, n+m=1, and representing the relative abundance in the polymer chain; n and m can be any number between 0-1.

In some embodiments, the heating or light process results in partial or complete loss of R₁, R₂, and/or R₃ in any composition in the end form. In some embodiments, the temperature has a range from 100-1000° C. In some embodiments, the thermal treatment or light process can be oxygen free or have control amount of oxygen.

In some embodiments, chemical structure (II) comprises random copolymer(s) or block copolymer(s).

In some embodiments, chemical structure (II) comprises one of chemical structures described in FIG. 5 or FIG. 6.

In some embodiments, the conductive polymer has the following chemical structure:

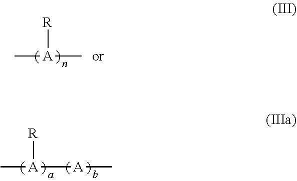

(also referred to as “the third generic structure”); wherein R is an alkyl chain or oligo ethyleoxide chain or alkyloxide chain of any length between 1-10000 carbon atoms. In some embodiments, R can be hydroxide terminated or carboxylic acid or carboxylate salt terminated.

In some embodiments, chemical structure (III) comprises random copolymer(s) or block copolymer(s).

The main chain with repeating unit of A forms a fully conjugated polymer backbone. Thermal or optical treatment of chemical structure (III) and/or (IIIa) leads to full or partial loss of the side chain R, while preserving the main polymer backbone structures. This process provides unique ion transport properties in the treated polymer film.

In some embodiments, the device comprises a lithium ion anode applications, a conductive polymer comprises an n-type of backbone structure. Such conductive polymer include: side chains substituted PPV, side chains substituted polyfluorene, and/or side chains substituted polyphenylene. See FIG. 9.

In some embodiments, the conductive polymer has the following chemical structure:

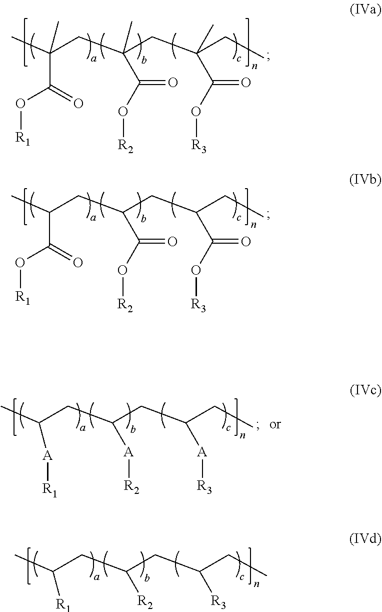

(also referred to as “the fourth generic structures”). In some embodiments, A is O, N, or S. In some embodiments, R₁ is

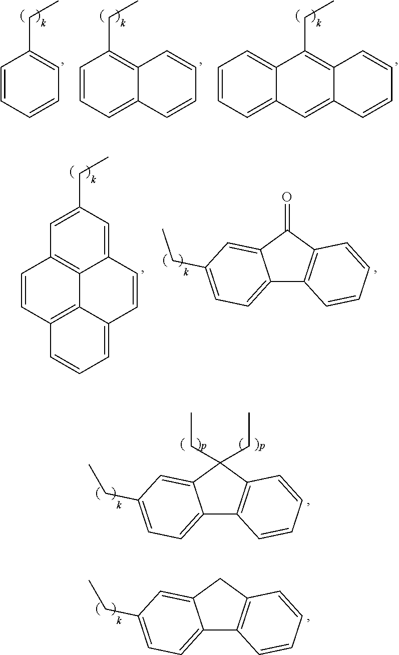

or —C≡N; wherein k is 0 to 100, the side chain connection to the aromatic moiety can be at any position, p is o to 100, the side chain can be branched. In some embodiments, R₁ is benzene, naphthalene, anthracene, pyrene, fluorenone, or fluorene, or nitrile. In some embodiments, k is 1 to 100, 1 to 50, 1 to 20, or 1 to 10. In some embodiments, p is 1 to 100, 1 to 50, 1 to 20, or 1 to 10. In some embodiments, R₂ is —(CH₂CH₂O)ₘCH₃, or —(CH₂)ₘCH₃, wherein m is 0 to 1000. In some embodiments, m is 1 to 100, 1 to 50, 1 to 20, or 1 to 10. In some embodiments, R₃ is H. In some embodiments, a+b+c=1, and representing the relative abundance in the polymer chain; a, b, and c can be any number between 0-1. See FIG. 10.

In some embodiments, chemical structure (IVa) to (IVd) comprises random copolymer(s) or block copolymer(s).

In some embodiments, the conductive polymer has a chemical structure, and active material and/or additive particles, described in U.S. Pat. No. 7,960,037 (Liu et al.); U.S. Pat. No. 8,852,461 (Liu et al.); U.S. Pat. No. 9,077,039 (Liu et al.); U.S. Pat. No. 9,653,734 (Liu et al.); U.S. Pat. No. 9,722,252 (Liu et al.); and, PCT International Patent Application No. PCT/US22/12376 (Liu et al.); which are hereby incorporated by reference.

In some embodiments, the conductive polymer has the following chemical structure: (X)ₙ; wherein X may be a conjugated homo polymer, a conjugated copolymer, or a linear polymer with conducting conjugated pending group. In some embodiments, the conductive polymer has the following chemical structure:

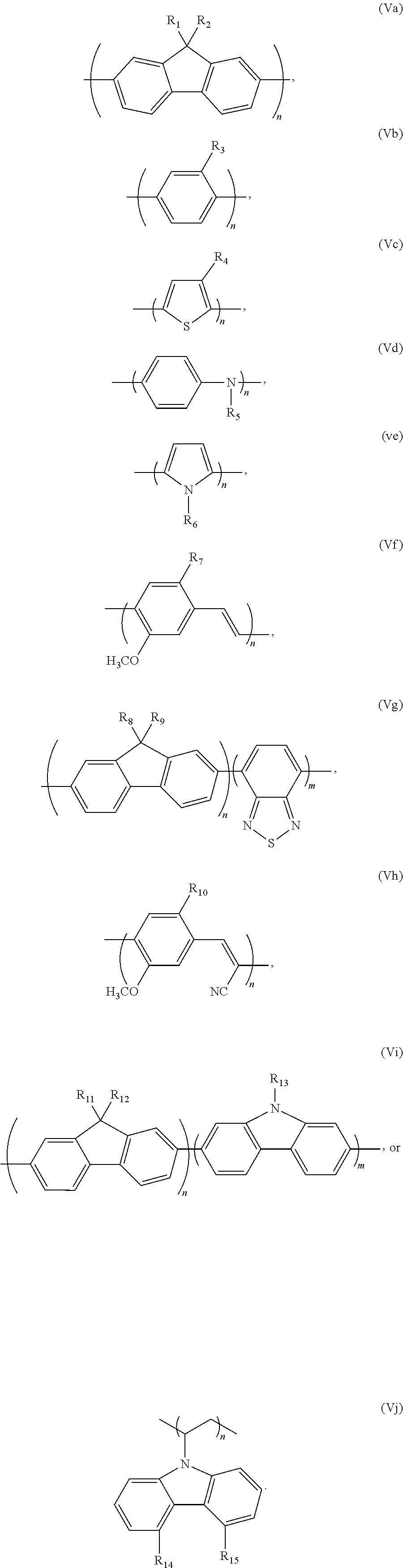

In some embodiments, the conductive polymer has the following chemical structure:

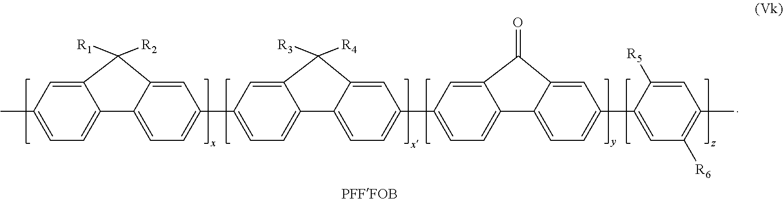

In some embodiments, x=0, x′ and y=>0, and z<=1, and x′+y+z=1. In some embodiments, R₃ and R₄ are each (CH₂)ₙCOOH, wherein n=0-8. In some embodiments, R₅ and R₆ are each independently H, COOH, or COOCH₃. In some embodiments, the number of COOH groups by copolymerizing x monomer into the main chains (as shown in Scheme 4). In some embodiments, by adjusting the ratio of x:x′, the number of —COOH groups can be controlled without changing the electronic properties of the conductive binders.

In some embodiments, 0<x, x′, y and z<=1 and x+x′+y+z=1. In some embodiments, R₁ and R₂ are each independently (CH₂)ₙCH₃, wherein n=0-8. In some embodiments, R₃ and R₄ are each independently (CH₂)ₙCOOH, wherein n=0-8. In some embodiments, R₅ and R₆ are each independently H, COOH, or COOCH₃. In some embodiments, the “x, x′” unit are each independently fluorene with either alkyl or alkylcarboxylic acid at the 9, 9′positions. In some embodiments, the “y” unit is fluorenone. In some embodiments, the H positions of the back bone of fluorenone and fluorene are each independently substituted with one or more of the following functional groups: COOH, F, Cl, Br, SO₃H, or the like groups.

In some embodiments, the conductive polymer is terminated by H or any other functional group, such as an alkyl, alkenyl, alkynyl, phenyl, aryl, hydroxyl, alkoxyl, halide, amino, thiol, aldehyde, carboxyl, or amide group.

The conductive polymers of chemical structures (IVa) to (IVj); wherein R₁-R₁₅ are selected from the group consisting of an oligoether group, an alkyl chain having a tertiary amine and an associated counter ion, and an alkyl chain having an SO₃ group and an associated counter ion; wherein said oligoether group terminates with a methyl group or hydroxyl group; and wherein n is between 2 and 1000.

In some embodiments, the alkyl chain has a tertiary amine and an associated counter ion and the alkyl chain has an SO₃ group and an associated counter ion may comprise 2-20 carbon atoms. R₁ and R₂ may each further comprise methyltriethyleneoxide. R₁ and R₂ may be independently the same group or a different group. In some embodiments, the conductive polymer is poly(2,7-9,9-(di(oxy-2,5,8-trioxadecane))fluorene) (“PFO”). A method of synthesizing PFO is taught in U.S. Pat. No. 7,960,037 (Liu et al.)

In some embodiments, the oligoether groups are selected from the group consisting of methyleneoxide, ethyleneoxide, trimethyleneoxide and tetramethyleneoxide.

In some embodiments, the conductive polymer comprises the chemical structure(s) (Va) to (Vj) comprises random copolymer(s) or block copolymer(s).

Further specific embodiments of the conductive polymer are described in Tianyu Zhu, et al. “Formation of hierarchically ordered structures in conductive polymers to enhance the performances of lithium-ion batteries” (Nature Energy, 8, 129-137, 2023), which is hereby incorporated by reference.

In some embodiments, the conductive polymer is a PFM. In some embodiments, the device comprises a Si composite electrode inContact with a conductive polymer, such as a first generic structure. In some embodiments, the thermal treatment is oxygen free. In some embodiments, oxygen (partially or entirely) can be used to adjust the treatment process. See FIG. 11.

### BRIEF DESCRIPTION OF THE DRAWINGS

The foregoing aspects and others will be readily appreciated by the skilled artisan from the following description of illustrative embodiments when read in conjunction with the accompanying drawings.

FIG. 1. The first generic structure of the polymers and their transformation when thermal treated at high temperature to lose the side chains R₁ and R₂.

FIG. 2. Possible molecular A segments and (A)ₙ segments of the ethylene oxide first generic structure of the polymers.

FIG. 3. Possible molecular E and F segments of the ethylene oxide first generic structure of the polymers.

FIG. 4. Example of PFM, the first generic structure of the polymers, chemical transformation during thermal treatment at 500° C. The PFM and Si can be processed into a polymer composite electrode, the pyrolysis at 500° C. transformed the PFM polymer in the electrode.

FIG. 5. The second generic structure of the polymers and examples.

FIG. 6. Possible molecular structures of the 2nd generic structure.

FIG. 7. An example of second generic structure of the polymers and their transformation when thermal treated at high temperature to lose the side chains. The substituted polyaniline with octyl side chains are synthesized through polyaniline (PANI) reacts with alkylidine. The thermal treatment of the substituted PANI gives back PANI and loses the octyl side chains to create ion conducting PANI for lithium-ion transport. The substituted PANI is used as binder with Si based particles and other components to form Si electrode. Thermal treatment forms ion conducting surface coating on Si particles to facilitate ion transport as well as provide Si surface stabilization. A. Synthesis of N-alkyl polyaniline. B. The polyaniline is doped by Cl⁻. The N-alkyl polyaniline is non-doped

FIG. 8. Another example of second generic structure of the polymers and their transformation when pyrolyzed at high temperature to loss the side chains. The substituted polythiophene with hexyl side chains can be synthesized through co-polymerization of the two monomers. The thermal treatment of the substituted polythiophene produce polythiophene and losses the hexyl side chains to create ion conducting layer for lithium-ion transport. The substituted polythiophene is used as binder with Si based particles and other components to form Si electrode. Thermal treatment forms ion conducting coating on Si particles to facilitate ion transport as well as provide Si surface stabilization.

FIG. 9. The third generic structure of the conjugated polymers and examples. A. Thermal and/or optical treatment. B. Examples of A. In some embodiments, A is a substituted PPV. In some embodiments, A is a substituted polyfluorene. In some embodiments, A is a substituted polyphenylene.

FIG. 10. The fourth generic structure of the polymers and examples, which are side chained functional polymers.

FIG. 11. Detailed example PFM and Si composite electrode 1st generic structure process and usages, as well as battery testing data.

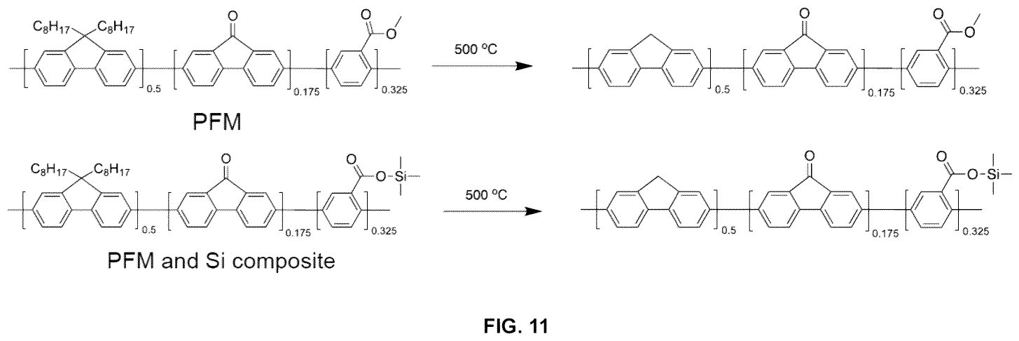

FIG. 12. PFM polymer thermal induced loss of dioctyl side chains and possible loss of carboxylate ester functional groups. DTA analysis of the structure transformation process indicated 400-500° C. is the decomposition temperature of the pure PFM polymer. It lost 39.7% weight during the pyrolysis process in the inert Ar atmosphere. The dioctyl chains account for total of 42% weight. Considering the sp3 bond and aryl side chains are the most vulnerable components on the aromatic structure, the loss of dioctyl side chains are most likely event in this case.

FIG. 13. The FTIR spectra support the losing of dioctyl side chains as the strong alkyl C—H stretching is gone in the thermal treated film sample. The disappearing of ester functionality may also indicate the partial removal of the carboxylate ester. The aryl components clearly remains in the pyrolyzed sample. The elimination of Tg of the PFM after thermal treatment also supports the removal of the dioctyl side chains. A. FTIR spectra of the PFM films of 80° C. drying, and after 500° C. heating in the inert atmosphere. B. DSC of the PFM films of 80° C. drying, and after 500° C. heating in the inert atmosphere.

FIG. 14. Different applications of the PFM polymers in lithium battery field.

FIG. 15. (A) In I vs. t plot and (B) lithium-ion diffusion coefficients of PFM and processed PFM determined by PITT measurements.

FIG. 16. Li/PFM500/Au solid-state device. First the PFM500 is doped, then the Li ion transport to the Au side to form Li—Au alloys.

FIG. 17. Synthetic pathways developed for PEM and PEF. PEM and PEF polymer can be processed with environmentally friendly solvents.

FIG. 18. 1H NMR spectrum for the synthesized PEM and PEF.

FIG. 19. FT-IR spectra of PEM thermally treated at different temperatures.

FIG. 20. Thermal stability analysis of PEM showing sequential losing functional groups.

FIG. 21. SAXS for PEM thermally treated at various temperatures.

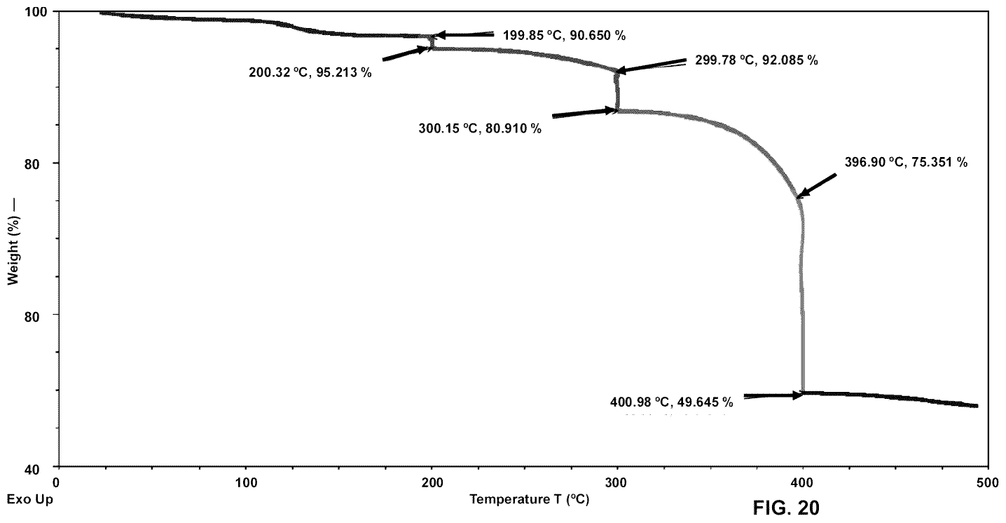

FIG. 22. The battery performance of Lithium-ion cells made with PEM400 binder and Si negative electrode. A. Lithium metal counter electrode. B. CE. C. Full cell performance. The figure shows PEM400 binder electrode electrochemical performance. Electrode composition (without processing): 60 wt % SiOx, 15 wt % PEM, 20 wt % graphite, 5 wt % Denka black. Cell configurations: SiOx-Li half cell and LFP-SiOx full cell. PEM400 anode electrode: 1.67 mg/cm2; composition of processed electrodes 64 wt % SiOx, 9.5 wt % PEM, 21 wt % graphite, 5.5 wt % Denka black. Electrolytes: Gen 2 EM/EMC=3:7, 10 wt % FEC. NMC 111 cathode electrode: 92.8 wt % NCM111, 4 wt % PVDF, 3.2 wt % acetylene black loading 4.5 mAh/cm².

FIG. 23. The electrochemical performance of PEF and heat treated PEF500 binder and Si electrode. PEF vs PEF500 binder electrode electrochemical performance. The figure shows a lithium metal counter electrode. Electrode composition (without processing): 60 wt % SiOx, 15 wt % PEF, 20 wt % graphite, 5 wt % Denka black. Cell configurations: SiOx-Li half cell, voltage cut-off 0.01-1.0 V, rate at C/10. PEF500 anode electrode: 1.60 mg/cm²; composition of processed electrodes 64 wt % SiOx, 9.5 wt % PEF, 21 wt % graphite, 5.5 wt % Denka black. Electrolytes: Gen 2 EM/EMC=3:7, 10 wt % FEC. NMC 111 cathode electrode: 92.8 wt % NCM111, 4 wt % PVDF, 3.2 wt % acetylene black loading 4.5 mAh/cm².

FIG. 24 shows scheme 1: synthesis of a monomer. When the benzenedicarboxylic acid staring material has only one CH₃ group, the reaction will end up with only one R═COOCH₃ group in the final product.

FIG. 25 shows scheme 2: synthesis of PFFO (or PF) conductive polymer.

FIG. 26 shows scheme 3: synthesis of conductive polymer with —COOCH₃ (PFFOMB or PFM) and —COOH (PFFOBA or PFA) groups on the side chains.

### DETAILED DESCRIPTION OF THE INVENTION

Before the invention is described in detail, it is to be understood that, unless otherwise indicated, this invention is not limited to particular sequences, expression vectors, enzymes, host microorganisms, or processes, as such may vary. It is also to be understood that the terminology used herein is for purposes of describing particular embodiments only, and is not intended to be limiting.

In this specification and in the claims that follow, reference will be made to a number of terms that shall be defined to have the following meanings:

The terms “optional” or “optionally” as used herein mean that the subsequently described feature or structure may or may not be present, or that the subsequently described event or circumstance may or may not occur, and that the description includes instances where a particular feature or structure is present and instances where the feature or structure is absent, or instances where the event or circumstance occurs and instances where it does not.

As used in the specification and the appended claims, the singular forms “a,” “an,” and “the” include plural referents unless the context clearly dictates otherwise. Thus, for example, reference to an “expression vector” includes a single expression vector as well as a plurality of expression vectors, either the same (e.g., the same operon) or different; reference to “cell” includes a single cell as well as a plurality of cells; and the like.

In this specification and in the claims that follow, reference will be made to a number of terms that shall be defined to have the following meanings:

The terms “optional” or “optionally” as used herein mean that the subsequently described feature or structure may or may not be present, or that the subsequently described event or circumstance may or may not occur, and that the description includes instances where a particular feature or structure is present and instances where the feature or structure is absent, or instances where the event or circumstance occurs and instances where it does not.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed within the invention. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included in the invention.

The term “about” refers to a value including 10% more than the stated value and 10% less than the stated value.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, the preferred methods and materials are now described. All publications mentioned herein are incorporated herein by reference to disclose and describe the methods and/or materials in connection with which the publications are cited.

Other objects, features, and advantages of the present invention will be apparent to one of skill in the art from the following detailed description and figures.

The solubility of PFM in different solvents (such as 5 mg PFM in about 0.8 mL different solvents) is: chloroform, toluene: good solubility; NMP: limited solubility; and DMSO: insoluble. NMP can be used as a solvent at ambient temperature or elevated temperature (such as higher than room temperature).

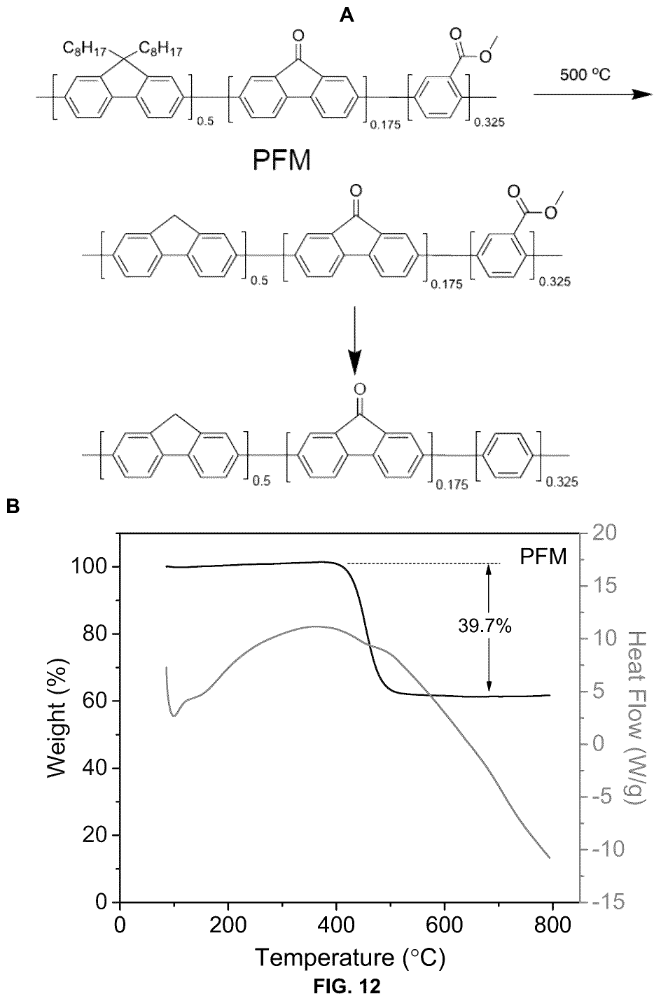

Thermal transformation of PFM leads to loss of one or more octyl functional groups, such as the concurrent or sequential losing the carboxylate ester. TGA analysis of the PFM polymer is shown in FIG. 12. PFM loses 39.7% of its own weight during heating, matched with two alkyl chains (C₈H₁₇, theoretical 42%). PFM-500 is prepared by heating PFM to 500° C. at a rate of 20° C./min and hold at 500° C. for 15 min under N₂. See FIG. 12.

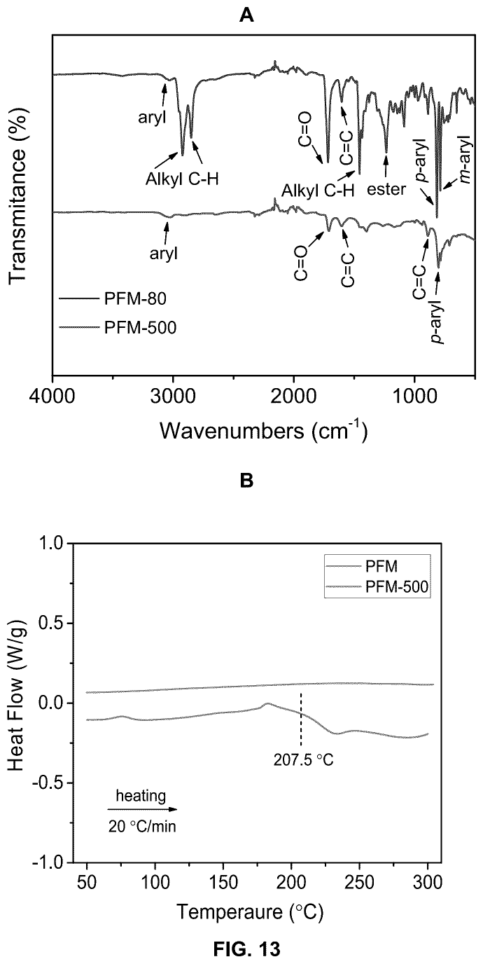

FIG. 13 shows the FTIR spectra support the losing of dioctyl side chains as the strong alkyl C—H stretching is gone in the thermal treated film sample. The sole function of the dioctyl chains on the PFM backbone is for solubility in the solvents for processing. The FTIR spectra show the losing of dioctyl functional groups from the PFM after about 500° C. heating in the inner atmosphere. DSC curves show the PFM glass transition temperature (Tg) at 207.5° C. After heating at 500° C., the Tg thermal transition at about 207.5° C. disappears, and no thermal transitions are detected at between about 50-300° C. Thermal treatment leads to loss octyl functional groups creates sub nano-porosity or molecular gaps for lithium-ion transport through the PFM membrane. Panel A shows FTIR spectra of the PFM films of 80° C. drying, and after 500° C. heating in the inert atmosphere. Panel B shows DSC of the PFM films of 80° C. drying, and after 500° C. heating in the inert atmosphere.

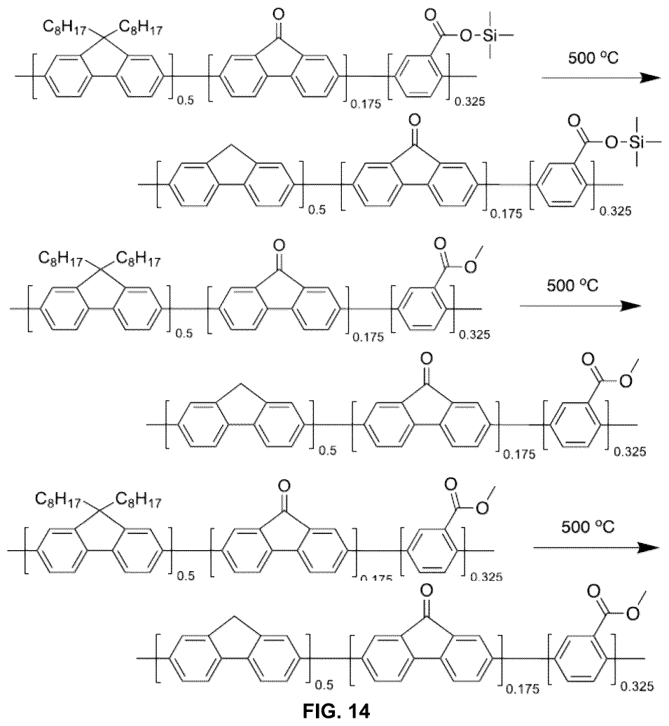

FIG. 14 shows different applications of the PFM polymers in lithium battery field. In some embodiments: (1) PFM and Si composite electrode: PFM binder and Si materials along with conductive additive acetylene black can form composite electrode for lithium-ion rechargeable battery negative electrode. (2) PFM/SiOx composite electrode: PFM binder and SiOx materials along with conductive additive acetylene black can form composite electrode for lithium-ion rechargeable battery negative electrode. (3) PFM/SiOx/carbon composite electrode: PFM binder, SiOx and graphite materials along with conductive additive acetylene black can form composite electrode for lithium-ion rechargeable battery negative electrode. In some embodiments, PFM and carbon (graphite) composite electrode: PFM binder and graphite materials along with conductive additive acetylene black can form composite electrode for lithium-ion rechargeable battery negative electrode. In some embodiments, PFM film on Cu electrode: PFM binder coated on the surface of a current collector such as Cu can be used as anode-less anode electrode for lithium metal rechargeable battery negative electrode. The PFM and treated PFM film protect the deposited Li metal. In some embodiments, a PFM film is on a Li electrode, such as PFM binder coated on the surface of a Li metal is used as anode electrode for lithium metal rechargeable battery negative electrode. The PFM and treated PFM film protect the deposited Li metal.

In some embodiments, the conductive polymer (such as PFM) is used in electrode making and processing and electrochemical cell. Examples of different applications of the conductive polymer (such as PFM) in lithium battery field include:

In some embodiments, the conductive polymer is used in composite electrode formulation, electrode casting and post treatment. SiO/C electrodes: 15 wt. % of PFM binder was dissolved in specific amount of chlorobenzene to form a homogeneous and vicious solution. Then, SiO/C (Shinetsu, 60 wt. %), graphite (Hitachi, 20 wt. %) and Denka black (5 wt. %) were sequentially added and thoroughly ground for 30 mins under room temperature. The slurry was coated on a copper foil by using a doctor blade (˜200 μm), and the coated electrode was then dried in the vacuum oven for 12 h at 80° C. The mass loading of active material (SiO/C) is 1.52±0.12 mg/cm2. The electrodes with the PFM binder are heated to a certain temperature (e.g. 500° C. for 15 mins with a ramp rate of 5° C./min) in a tube furnace under ultrapure argon flow to obtain the final electrodes. Experimentally, a mass retention of ˜95% for the SiO/C electrodes (˜97% for the graphite electrodes) was observed due to thermal decomposition of the PFM binder.

In some embodiments, the conductive polymer is used in cell fabrication. Coin cells (CR2032, MTI Corp.) were assembled in an argon-filled glovebox. Celgard 2400 was used as the separator. Lithium-ion electrolyte (Gen 2) was obtained from the Argonne National Lab, containing 1.2M LiPF6 in ethylene carbonate, diethyl carbonate (EC/DEC=3/7 w/w) without other additives. The PFM based Si electrode is coupled with Li metal counter electrode to fabricate testing cells. The PFM based Si electrode is also coupled with LiFePO4 cathode to fabricate lithium ion cells.

In some embodiments, the conductive polymer is used in lithium metal electrode or anode-less electrode fabrication. The PFM chlorobenzene solution is coated either on Cu current collector or on Al on Cu or on Li directly. The PFM coated Cu electrode was heated to a certain temperature (e.g. 500° C. for 15 mins with a ramp rate of 5° C./min) in a tube furnace under ultrapure argon flow to obtain the final PFM coated Cu electrodes or PFM coated Al/Cu electrodes, or PFM coated Li electrode.

In some embodiments, the conductive polymer is used in cell fabrication. Coin cells (CR2032, MTI Corp.) were assembled in an argon-filled glovebox. Celgard 2400 was used as the separator. Lithium-ion electrolyte (Gen 2) was obtained from the Argonne National Lab, containing 1.2M LiPF6 in ethylene carbonate, diethyl carbonate (EC/DEC=3/7 w/w) without other additives. The PFM coated Cu or PFM coated Al/Cu or PFM coated Li metal electrode is coupled with Li metal counter electrode to fabricate testing cells. The PFM coated Cu or PFM coated Al/Cu or PFM coated Li metal electrode Si electrode is also coupled with LiFePO4 cathode to fabricate lithium metal full cells.

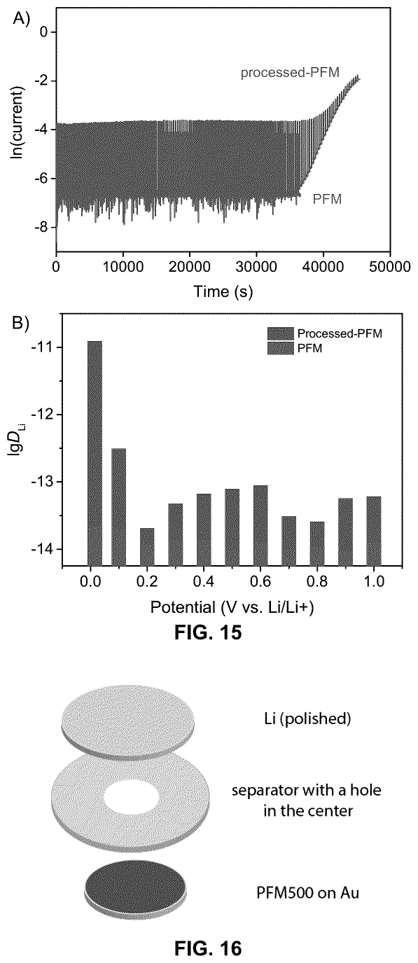

FIG. 15 shows Li-ion diffusion coefficients measurement in HOS-PFM film. (A) In I vs. t plot and (B) lithium-ion diffusion coefficients of PFM and processed PFM determined by PITT measurements.

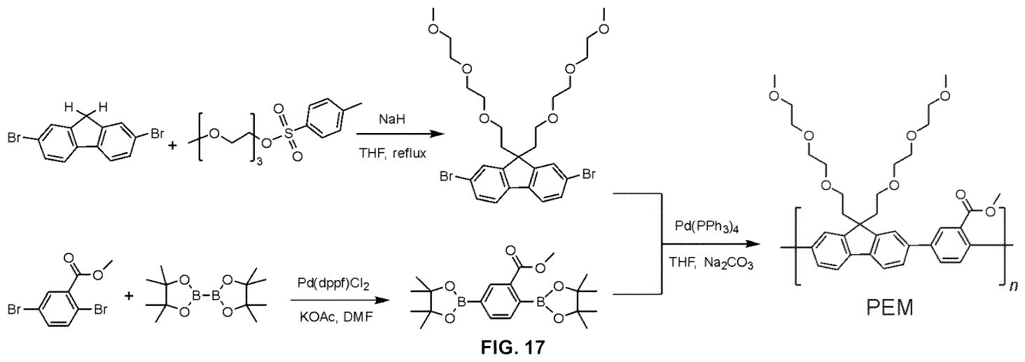

In some embodiments, the device is a Li/PFM500/Au solid-state device. First the PFM500 is doped, then the Li ion transport to the Au side to form Li—Au alloys. FIG. 16 shows the demonstration of solid-state reaction of the Li ion doping of the HOS-PFM film, and Li ion solid-state transport through the doped film, and formation of the Li—Au alloys. The separator is a plastic insulating ring with a circular opening in the middle to define the Li metal contact area to the PFM500 (HOS-PFM) film. In some embodiments, the device comprises an Au electrode side, a middle round disk that is the gold electrode/substrate, where PFM500 is coated on the opposite side, a plastic ring, and a compressed Li metal. The entire device is in an Ar filled glovebox.

In some embodiments, the device is a Li/PFM500/Au device. Such a device is demonstrated: solid-state reaction of the Li ion doping of the HOS-PFM film, and Li ion solid-state transport through the doped film, and formation of the Li—Au alloys. PFM500 side in contact with Li metal, after peeling off the Li metal. The PFM500 transformed during the doping process, but physically intact. XRD demonstrates the formation of Li—Au alloy.

In some embodiments, the device is a Na/PFM500/Au solid-state device. First the PFM500 is doped, then the Na ion transport to the Au side to form Na—Au alloys. Such a device is demonstrated: solid-state reaction of the Na ion doping of the HOS-PFM film, and Na ion solid-state transport through the doped film. In some embodiments, the device comprises a middle round disk is the gold substrate, where PFM500 is coated on the opposite side, a plastic ring, and compressed Na metal. The entire device is in an Ar filled glovebox. The voltage across the device is monitored between the Na and Au electrode. When the Na metal is just pressed to the PFM500, the Na and Au showed an open circuitry state with no measurable/stable voltage, then a high stable voltage is observed, at last the voltage become very low −60-80 uV. This is consistent with first doping of the PFM500, and formation of Na—Au alloys. However, the alloy is not detectable with XRD due to the insignificant amount of formation at ambient temperature.

Examples of different applications of the conductive polymers, such as in battery field, are as follows: (1) The polymer can be dissolved in a solvent or solvents and mixed with active materials particles and other additive particles to form a slurry. The slurry can be coated on the surface of a current collector and dried into a composite laminate film. The film then be thermal treated to transform into the final form. This laminate can be used in combination with liquid electrolyte, gel or solid-state electrolytes. (2) The polymers can be dissolved in a selected solvent and coated on to the active materials surface and dried and thermal treated at the selected temperature to transform into the final form to form the coating and protective layer. The coated particles can be used as battery materials. (3) The polymer can be directly coated on a flat surface such as carbon, Si, Al, Li, Sn film surface and be thermal treated to transform into the final form. (4) The usages can be for lithium battery, sodium battery, Mg and Zn battery system. (5) The usages are not limited to battery application, but can be used to any applications need to have ion or electron mobility.

It is to be understood that, while the invention has been described in conjunction with the preferred specific embodiments thereof, the foregoing description is intended to illustrate and not limit the scope of the invention. Other aspects, advantages, and modifications within the scope of the invention will be apparent to those skilled in the art to which the invention pertains.

All patents, patent applications, and publications mentioned herein are hereby incorporated by reference in their entireties.

The invention having been described, the following examples are offered to illustrate the subject invention by way of illustration, not by way of limitation.

### Example 1

### Modified PANI and Si Composite Electrode 2nd Generic Structure Synthesis, Process and Usages

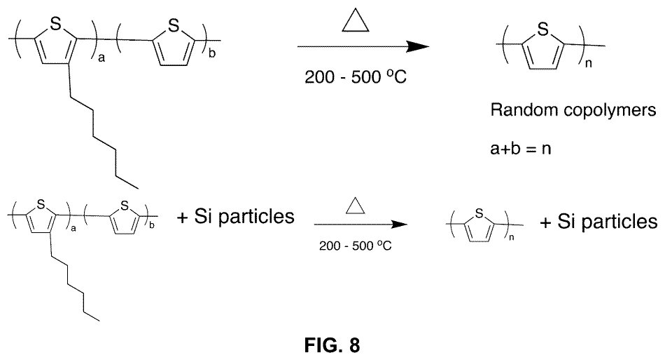

An example of second generic structure of the polymers and their transformation when thermal treated at high temperature to lose the side chains. The substituted polyaniline with octyl side chains are synthesized through polyaniline (PANI) reacts with alkylidine. The thermal treatment of the substituted PANI gives back PANI and loses the octyl side chains to create ion conducting PANI for lithium-ion transport. The substituted PANI is used as binder with Si based particles and other components to form Si electrode. Thermal treatment forms ion conducting surface coating on Si particles to facilitate ion transport as well as provide Si surface stabilization. See FIG. 7.

Panel A shows the synthesis of N-alkyl polyaniline—Commercial doped polyaniline (Honeywell Fluka, 200 mg) was dissolved in 20 mL dry tetrahydrofuran (THF, Sigma-Aldrich) under nitrogen atmosphere. Then, sodium hydride (NaH, 172 mg, 60% dispersion mineral oil, Sigma-Aldrich) was slowly added to the reaction solution at 0° C. The mixture was stirred for 1 hour in an ice bath to allow the deprotonation of polyaniline. A 10 vol % solution of 1-iodooctane (1.44 g, Sigma-Aldrich) in THF was then added and the solution was stirred for 12 h under room temperature. The final polymer product was obtained by evaporating the THF and thoroughly washed with acetone and methanol to remove any sodium salts and unreacted alkyl halide. The obtained dark-grey precipitate (232 mg) was dried under vacuum at 60° C. for 12 h to remove any remaining solvent. In panel B the polyaniline is doped by Cl⁻, and the N-alkyl polyaniline is non-doped.

### Example 2

### Modified Polythiophene and Si Composite Electrode 2nd Generic Structure Synthesis, Process and Usages

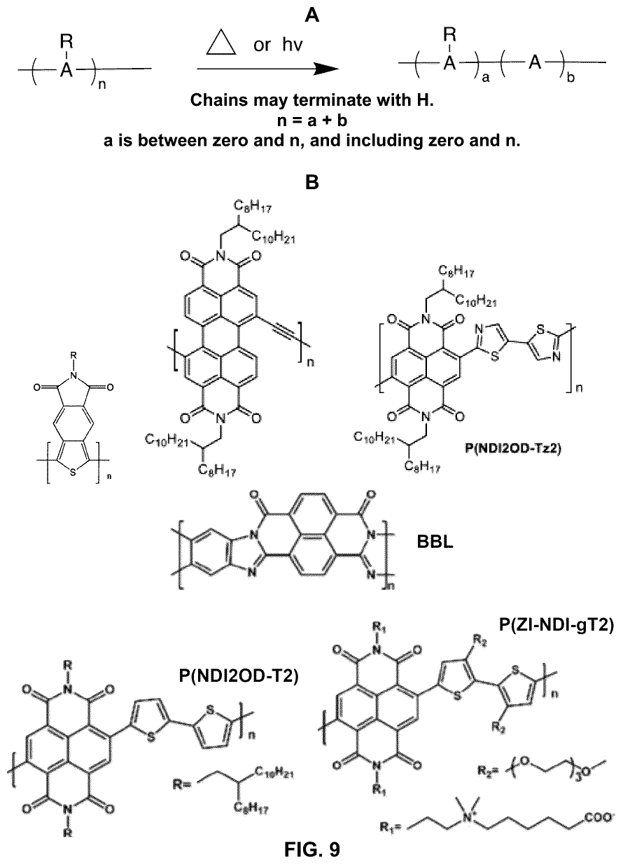

Another example of second generic structure of the polymers and their transformation when pyrolyzed at high temperature to loss the side chains. The substituted polythiophene with hexyl side chains can be synthesized through co-polymerization of the two monomers. The thermal treatment of the substituted polythiophene produce polythiophene and losses the hexyl side chains to create ion conducting layer for lithium-ion transport. The substituted polythiophene is used as binder with Si based particles and other components to form Si electrode. Thermal treatment forms ion conducting coating on Si particles to facilitate ion transport as well as provide Si surface stabilization. See FIG. 8.

### Example 3

### Mixed Solid-State Ionic-Electronic Polymer Conductors for Electrochemical Devices

The present invention describes the design of a mixed ionic-electronic conducting polymer that can be directly used or processed for lithium batteries.

(1) This synthetic polymer has a rigid backbone for electron conduction and mechanical robustness, triethylene oxide side chains for better solubility and ion transport, and methyl ester for adhesion.

(2) This polymer can be thermally processed to cleave side-chains and form well-defined morphology for better charge transport. Processing temperature can be lower (300-400° C.) compared to our previous findings (about 500° C.).

(3) Unlike other conductive we proposed earlier, this polymer can be processed with a variety of non-toxic organic solvents including NMP, DMSO.

(4) This polymer can support stable cycling of micro-sized silicon with high areal loading in conventional cell design and carbonate electrolytes.

### Experimental Details

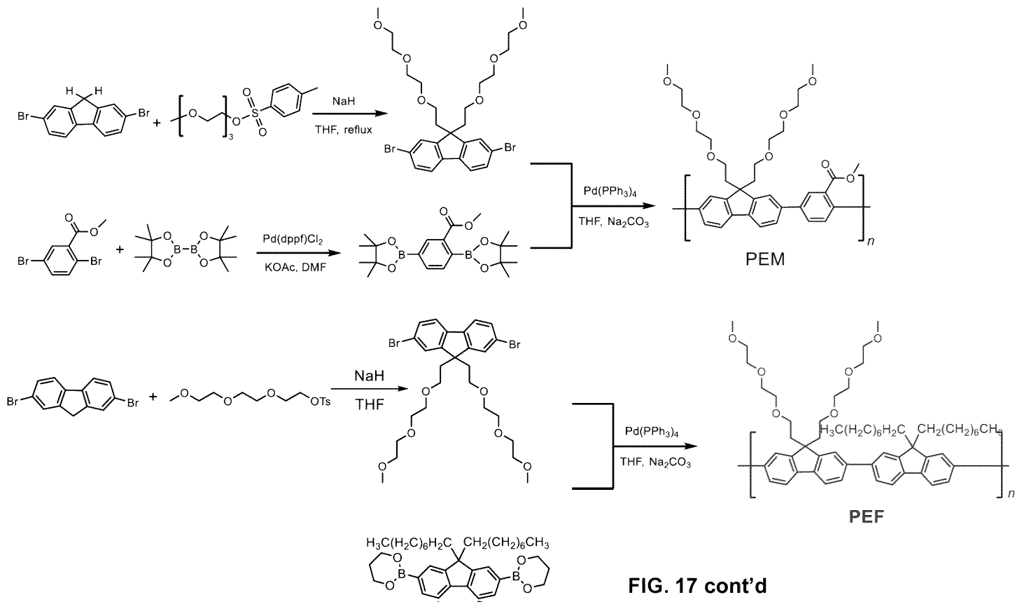

Monomer synthesis. The synthetic route was shown in FIG. 17. The monomer 2,7-dibromo-9,9(di(oxy-2,5,8-trioxadecane))-fluorene was synthesized according to literature report (JACS. 2013, 135, 12048). To prepare methyl 2,5-bis(4,4,5,5-tetramethyl-1,3,2-dioxaborolan-2-yl)benzoate, the ratio of reactant was methyl 3,5-dibromobenzoate:B2Pin2:Pd catalyst:potassium acetate (KOAc)=1.0:2.5:0.1:2.5 and the reaction was conducted under 80° C. DMF was used as reaction solvent with a reactant concertation of 0.1 mmol/mL. Pd catalyst was first removed by precipitation in hexane. The rest of reaction mixture was passing a column with hexane/EA=6/1. The product has a polarity slightly higher than B2Pin2. The product was purified by column chromatography and recrystallization in a scale of 2 g. The product is a viscous liquid after evaporating the solvents and quickly crystalized under ambient conditions. ¹H NMR (500 MHz, CDCl₃): δ=7.94 (d, phenol proton, 1H), 7.52 (d, phenol proton, 2H), 3.92 (s, methyl ester proton on benzene ring, 3H), 1.45, 1.37 (s, methyl on boronic acid pinacol ester, 24H).

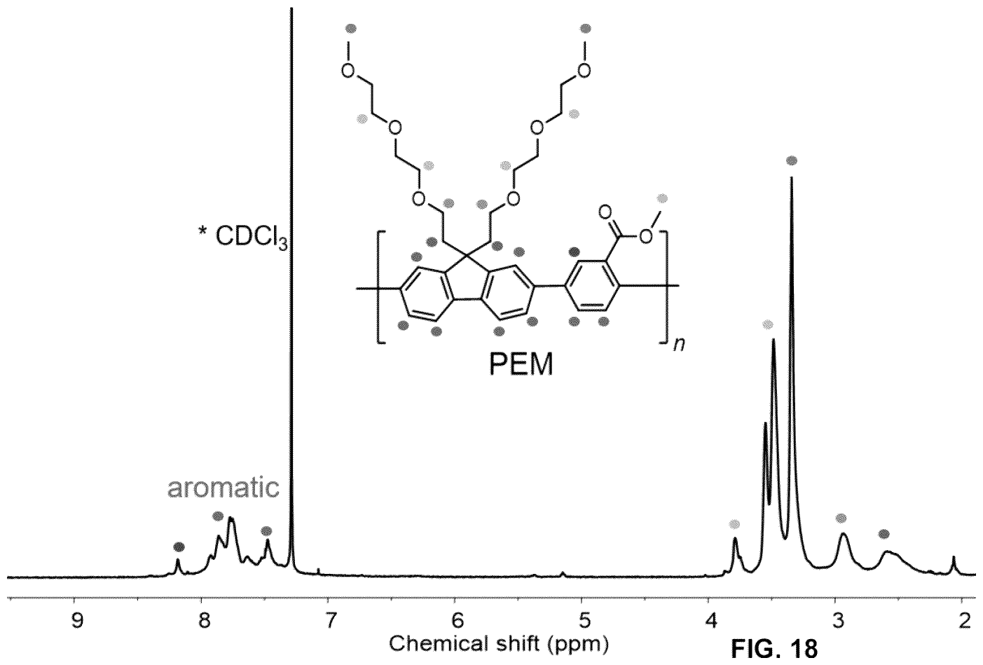

Polymer synthesis. Both monomers have a purity of >99% after multiple purification steps. The Suzuki polymerization reaction was conducted under argon atmosphere. The solution turns viscous after 3-day reaction. The product was precipitate in excess methanol and further dried under vacuum oven to obtain brown color fiber. This polymer was named as PEM, E stands for ethylene glycol chain, M stands for methyl benzoate. The chemical structure of the resulting polymer was confirmed by ¹H NMR (FIG. 18). The polymer can be prepared in multi-gram scale.

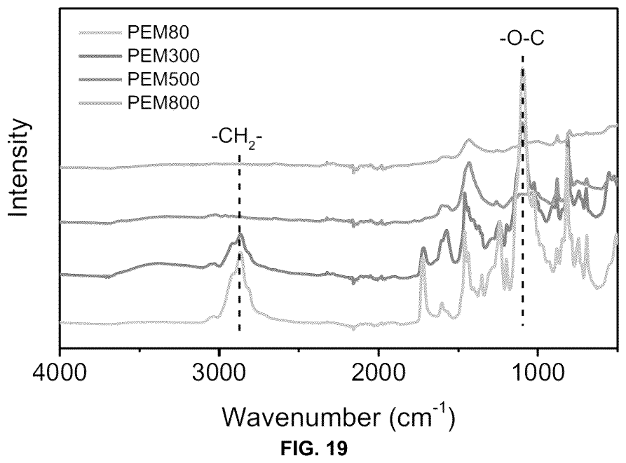

Thermal gravity analysis. Stepwise heating procedure: the polymer was heated up at a rate of 10° C./min and held at 200, 300, 400° C. for 30 mins, respectively to monitor the weight loss at certain temperature. Corresponding results are showed in FIG. 20. The major weight loss still turns to be above 350° C., which is associated with sequential losing of triethylene oxide side-chains. The first weight loss before 200° C. could be some moistures absorbed. Weight ratios by calculation: triethylene oxide side chain 49.8 wt. %, methyl ester 10.0 wt. %, backbone 40.2 wt. %.

Solubility analysis. The solubility of PEM in common organic solvents was tested by adding 1 mg polymer into 0.2 mL organic solvent. Unlike many other polyfluorene polymer, there are many organic solvent can fully dissolve this polymer, including chloroform, 1-methyl-2-pyrrolidone (NMP), chlorobenzene, dimethyl sulfoxide (DMSO). The polymer is insoluble in water, but swells in ethanol. The solubility of PEM in common organic solvents is important for battery electrode manufacturing.

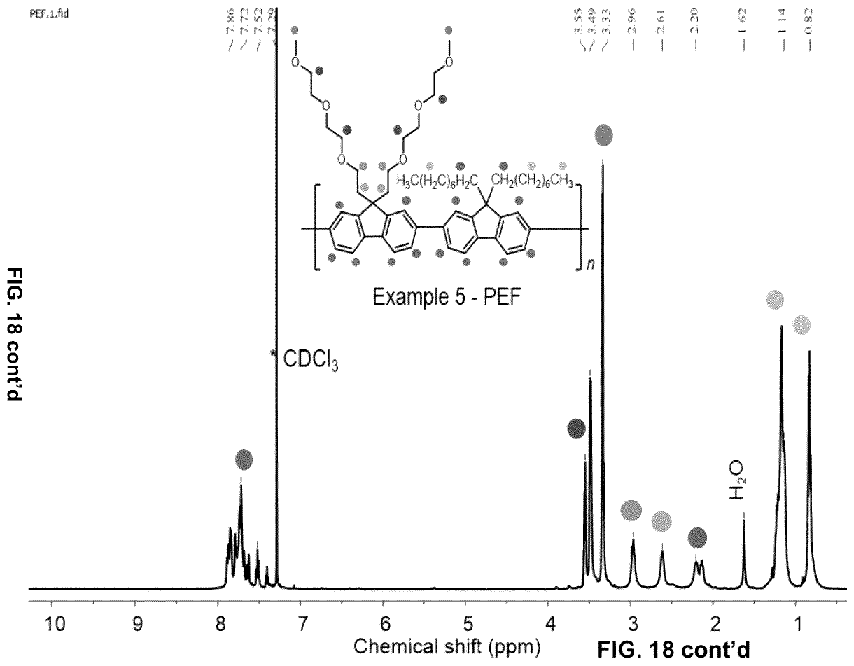

Chemical structural analysis. Beside ¹H NMR, Fourier-transform infrared spectroscopy (FT-IR) was used to confirm the chemical structure of polymer in solid state and its evolution with thermal process (FIG. 19). Most side-chain remains by treating at 300° C. for 8 h. Thermal processing at 500 C and higher and completely remove triethylene oxide side chains.

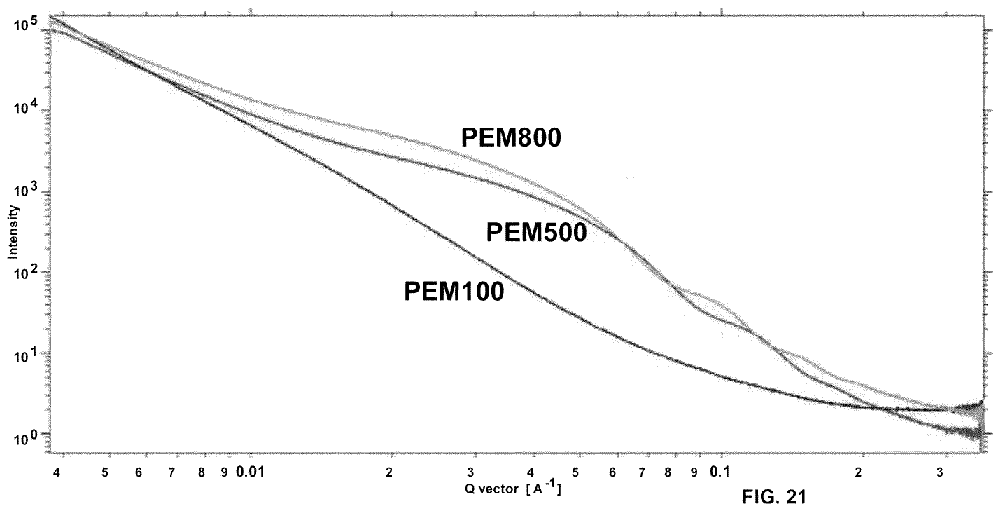

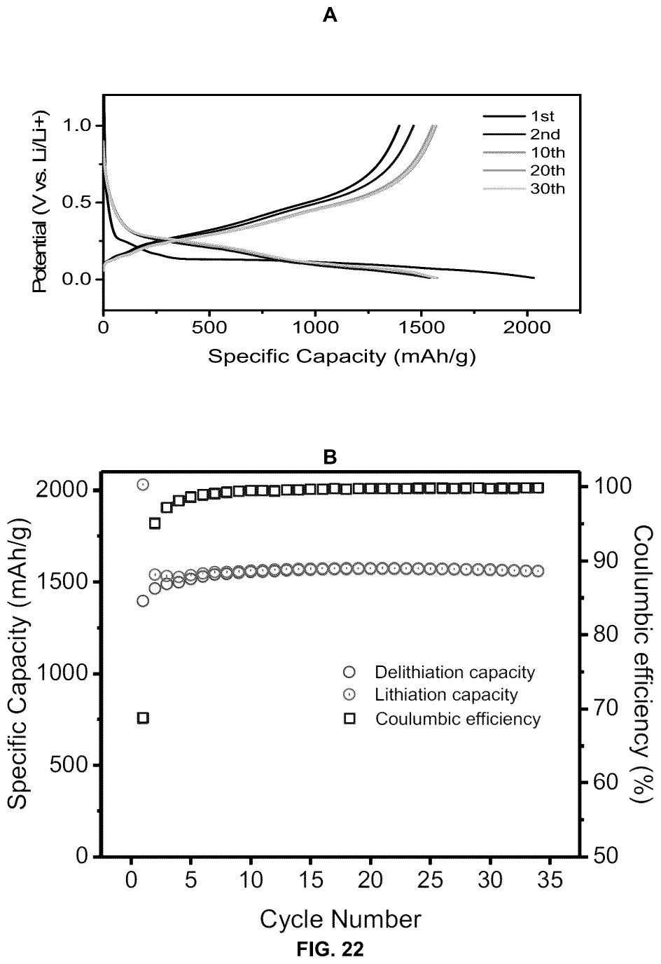

Electrode fabrication. PEM binder was firstly dissolved in organic solvent to form a homogeneous solution (5-10 wt. %). The organic solvent used for electrode fabrication can be 1-methyl-2-pyrrolidone (NMP), chloroform, chlorobenzene, dimethyl sulfoxide (DMSO), or other commonly used organics that can dissolve PEM and disperse active materials. Silicon (or silicon oxide) was used as active material, graphite and Denka black were used as conducting agent. Active material and carbon additives were sequentially added into the binder solution and thoroughly mixed under room temperature. The weight ratios of PEM, SiOₓ, graphite and Denka black are 15%, 60%, 20% and 5%, respectively for the data presented in FIGS. 22 and 23, and Table 2. The slurry was further coated on a copper foil using a doctor blade and dried at 80° C. in a vacuum oven. The resulting anode has an area capacity of 2.0-4.5 mAh/cm² based on the coating thickness. FIGS. 22 and 23, and Table 2 presents a high loading anode with an areal capacity of 4.2 mAh/cm².

Electrode processing. To enhance the charge transport property of the polymer coating layer, the electrode was thermal processed under elevated temperature (100-500° C.) and inert atmosphere.

Coin cell fabrication. Coin cell (CR2032, MTI Corp.) assembly was performed in an argon-filled glovebox. A 14.42 mm diameter disk was punched out as a working electrode. Lithium chip (16.0 mm in diameter, MTI Corp.) was used as the counter electrode. 60 μL of 1.2 M LiPF₆ in EC/EMC=3/7 electrolyte (Generation 2, obtained from Argonne National Lab) with (or without) fluoroethylene carbonate (FEC) was used for various electrochemical tests. Celgard 2400 separator (1.7 cm in diameter) was placed between the working electrode and the counter electrode.

Coin cell testing. Cycling performance of the assembled coin cells was evaluated in a thermal chamber at 30° C. with a Maccor Series 4000 Battery Test System. The cut-off voltages for cell testing are 0.01 to 1.0 V for half cells assuming a theoretical capacity of 1,200 mAh/g for SiOₓ. In galvanostatically cycling tests, the half cells were cycled at a rate of C/10. The C rate here was determined by the theoretical capacity of SiOₓ. The specific capacity of the composite anode material was reported based on the amount of SiOx considering the carbon additives contribute to less than 10% of overall capacity.

PEM is tested in different solvents (1 mg polymer, 0.2 mL solvent) (Table 1).

TABLE 1
Solubility of PEM in common organic solvents.

| Water | Ethanol | NMP | Chlorobenzene | Chloroform | DMSO |
|---|---|---|---|---|---|
| Completely insoluble, | Slight swelling, | Fully soluble | | | |
| Non-swelling | insoluble | | | | |

TABLE 2
Coulombic efficiency (%) for SiOₓ—Li half-cell cycling.

| Temp (° C.) | Cycle 1 | Cycle 2 | Cycle 3 | Cycle 4 | Cycle 5 | Cycle 6 | Cycle 10 | Cycle 20 | Cycle 30 |
|---|---|---|---|---|---|---|---|---|---|
| 80 | 15.66 | 49.07 | 69.96 | 75.41 | 80.07 | 87.12 | — | — | — |
| 400 | 68.74 | 95.06 | 97.16 | 98.10 | 98.58 | 98.88 | 99.45 | 99.72 | 99.77 |

### Example 4

### Mixed Solid-State Ionic-Electronic Polymer Conductors for Electrochemical Devices

The present invention describes a new type of polymeric based solid-state ion conductors, where the ion transport is not based on solvation or segmental motion. This kind of ion conductors is a ubiquitous ion conductor for all type ions, and ions are transported via diffusion at significant rate at a long distance. This kind of ion conductors are also electron conducting, making them mixed ionic and electric conductors.

Here describe the chemistry and formation of conductive polymers with ordered structure and no blocking moiety, and their use as an ion transport media. This kind of polymer media needs no solvent or plasticizer to solvate the ions in the polymer matrix and no solvation sites needed on the polymer chains, and no segmental motion of the polymer matrix needed. This kind of polymer transport ions ubiquitously, that monovalent and multivalent ions of positive or negative can moved freely in the polymer matrix by diffusion. The polymer matrix needs to be an electrically conductive polymer which can provide counter charges to the mobile ions. The electrically conductive polymer needs to have minimum electron insulating moieties. Here described a specific class of example of the making and processing of this type of ion conducting polymer, acronym PFM.

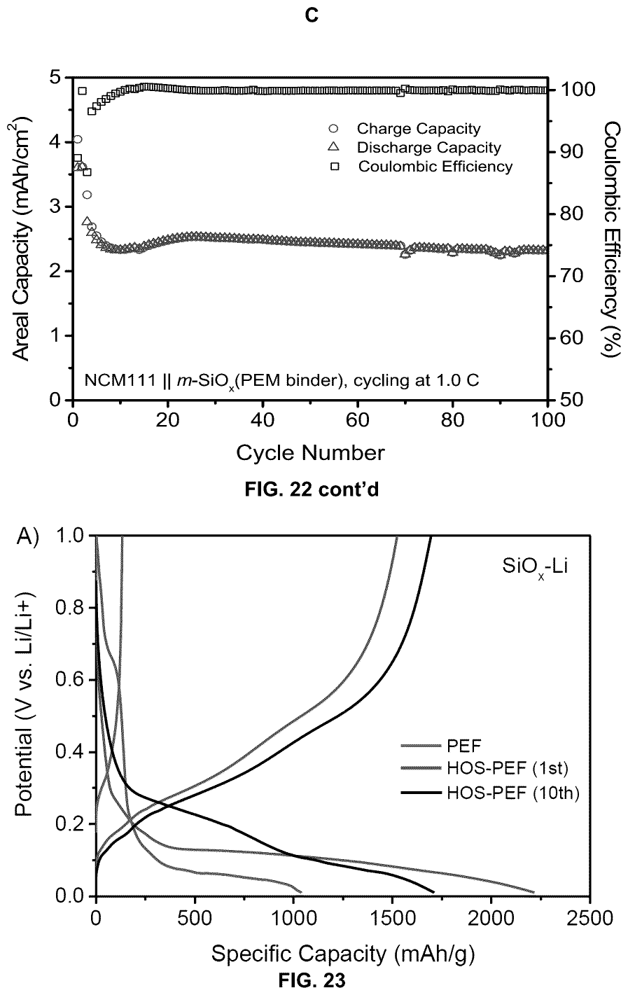

Synthesize of the class of conductive polymer. A fabrication method for the synthesis of one embodiment of the dual charge conductor polymer of this invention is as set forth below. First presented is a means for preparing one of the monomers used in polymer formation, i.e. 2,5-dibromo-1,4-benzenedicarboxylic acid. FIG. 24 shows scheme 1, synthesis of monomer. When the benzenedicarboxylic acid staring material has only one CH₃ group, the reaction will end up with only one R═COOCH₃ group in the final product.

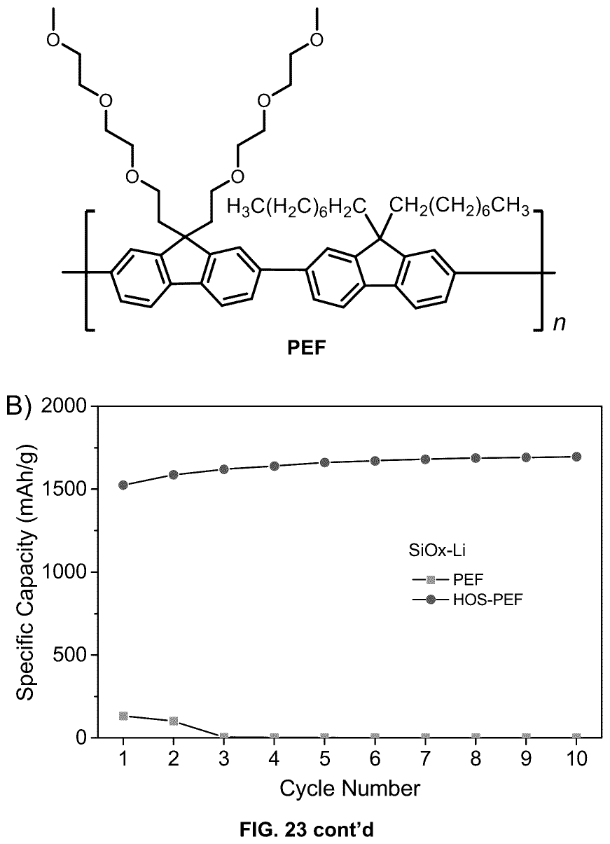

Synthesis of polymeric PFFO (poly(9,9-dioctylfluorene-co-fluorenone)) (PFFP is the same acronym as PF). Exemplary of a method for forming the polymer of this invention is provided with respect to the one embodiment, according to the formula below. A mixture of 9,9-dioctylfluorene-2,7-diboronic acid bis(1,3-propanediol) ester (0.83 g, 1.5 mmol) commercially available from Sigma-Aldrich Company, 2,7-dibromo-9-fluorenone (0.50 g, 1.5 mmol), (PPh₃)₄Pd(0) (0.085 g, 0.07 mmol) and several drops of Aliquat 336 in a mixture of 10 mL of THF (tetrahydrofuran) and 4.5 mL of 2 M Na₂CO₃ solution was refluxed with vigorous stirring for 72 hours under an argon atmosphere. During the polymerization, a brownish solid precipitated out of solution. The solid was collected and purified by Soxhlet extraction with acetone as solvent for two days with a yield of 86%. FIG. 25 shows scheme 2: Synthesis of PFFO (or PF) conductive polymer.

Synthesis of PFFOMB (poly(9,9-dioctylfluorene-co-fluorenone-co-methylbenzoic acid)) (PFFOMB is the same acronym as PFM). A mixture of 9,9-dioctylfluorene-2,7-diboronic acid bis(1,3-propanediol) ester (0.80 g, 1.43 mmol), 2,7-dibromo-9-fluorenone (0.24 g, 0.72 mmol), methyl 2,5-dibromobenzoate (0.21 g, 0.72 mmol), (PPh₃)₄Pd(0) (0.082 g, 0.072 mmol) and several drops of Aliquat 336 in a mixture of 13 mL of THF (tetrahydrofuran) and 5 mL of 2 M Na₂CO₃ solution was refluxed with vigorous stirring for 72 h under an argon atmosphere. After reaction stopped, the solution was concentrated by vacuum evaporation and the polymer was precipitated from methanol. The resulting polymer was further purified by precipitating from methanol twice. The final polymer was collected by suction filtration and dried under vacuum with a yield of 87%.

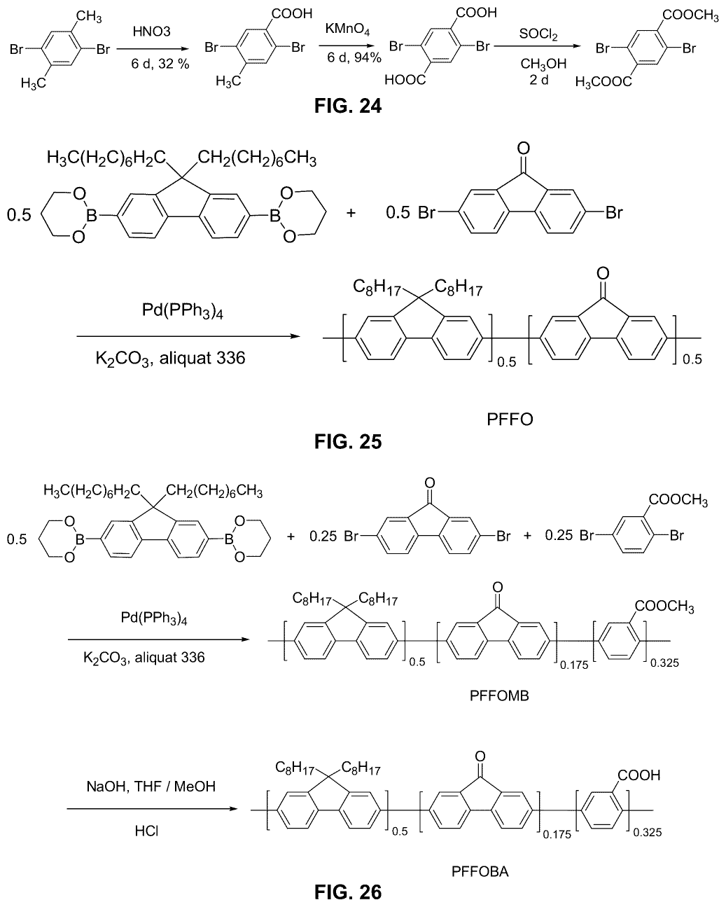

Synthesis of PFFOBA (poly(9,9-dioctylfluorene-co-fluorenone-co-benzoic acid)) (PFFOBA is the same acronym as PFA). A mixture of PFFOMB (0.36 g) and KOH (2 g, 35 mmol) in 20 mL of THF and 2 mL of H₂O was refluxed for 48 h under an argon atmosphere. After reaction stopped, the solution was concentrated by vacuum evaporation and polymer was precipitated from methanol. The resulting polymer was suspended in 10 mL of concentrated H₂SO₄ with vigorous stirring for 12 hours. The final product was filtered, washed with water and dried with a yield of 96%. FIG. 26 shows scheme 3. Conductive polymer with —COOCH₃ (PFFOMB or PFM) and —COOH (PFFOBA or PFA) groups on the side chains.

It has been found that the presence of —COOH groups serves to increase the bindability of the polymer to the silicon particles or any surfaces of the electrode. In particular, one can position carboxylic acid groups in connection with the 9^{th} position of fluorene backbone. Scheme 3 gives the general structure of this type of polymer.

In some embodiments, additional —COOH and —COOMe groups in the side chains can be incorporated to improve binder properties. In some embodiments, the conductive polymer is chemical structure (Vk); wherein x=0, x′ and y=>0, and z<=1, and x′+y+z=1, R₃ and R₄ can be (CH₂)ₙCOOH, n=0-8, and R₅ and R₆ can be any combination of H, COOH and COOCH₃.

Control the number of COOH or COOMe groups. Another variation is to adjust the number of COOH groups by copolymerizing x monomer into the main chains as shown in Scheme 4. By adjusting the ratio of x:x′, the number of —COOH groups can be controlled without changing the electronic properties of the conductive binders.

In some embodiments, the conductive polymer is chemical structure (Vk); wherein 0<x, x′, y and z<=1 and x+x′+y+z=1; R₁ and R₂ can be (CH₂)CH₃, n=0-8; R₃ and R₄ can be (CH₂)ₙCOOH, n=0-8; R₅ and R₆ can be any combination of H, COOH and COOCH₃; and the “x, x′” unit is fluorene with either alkyl or alkylcarboxylic acid at the 9, 9′positions; the “y” unit is fluorenone, The H positions of the back bone of fluorenon and fluorene also can be substituted with functional groups such as COOH, F, Cl, Br, SO₃H, or the like groups.

Processing of the PFM polymer into dual charge conductive thin film. PFM polymer was dissolved in specific amount of chlorobenzene to form a homogeneous and viscous solution (e.g. 80 mg/mL). The solution was then cast on to a thin film substrate (e.g. Cu of 16 μm thick or Au of 10 μm thick) with a 100-150 um gap doctor blade. The coating was allowed to dry at ambient temperature. The solution making and film forming were done at an Ar filled glovebox. The as coated film is 10-30 μm micron thick, and has a yellow color. The film was heated to a certain temperature (e.g. 500° C. for 15 mins with a ramp rate of 5° C./min) in a tube furnace under ultrapure argon flow to obtain the final electrodes. The final product is 4-16 μm thick dark colored film coating on the substrate.

Free-standing PFM films for structural characterization were prepared by polymer solution casting. Generally, PFM sample was dissolved in chlorobenzene with a concentration of 80 mg/mL and stirred for few hours at room temperature. The solution was then poured onto a clean glass slide and dried at room temperature for 12 h. Then, the film was dried in a vacuum oven at 80° C. for 12 h, cooled down to room temperature and peeled off from glass slide to obtain the free-standing films. The pristine PFM film has an orange color. PFM films after thermal decomposition was obtained by heating the films to a certain temperature (e.g. 500° C. for 15 mins with a ramp rate of 5° C./min) under ultrapure argon flow. The resulting films are free-standing and shows a dark grey color. The polymer achieves order molecular structure through thermal treatment. When the side chains decomposed through thermal treatment, the order structure becomes continuous, which we name it HOS-PFM. The polymer after thermal treatment also can be named by the treatment temperature as PFM500, which is the PFM polymer thermal treated at 500° C.

The FT-IR spectra of PFM films (pristine and after heating) were recorded on Nicolet iS50 FTIR (ThermoFisher, Waltham MA, USA) with attenuated total reflectance (ATR) function.

The surface images of composite electrodes (or binder films) on the copper foil were collected with JSM-7500F SEM (JOEL Ltd., Tokyo, Japan) with an accelerating voltage of 12 kV under high vacuum at room temperature. The samples were thoroughly dried under vacuum before the morphology measurement.

### Formation and Processing of Composite Electrode for Solid-State Battery Application

SiO/C electrodes: 15 wt. % of PFM binder was dissolved in specific amount of chlorobenzene to form a homogeneous and vicious solution. Then, SiO/C (Shinetsu, 60 wt. %), graphite (Hitachi, 20 wt. %) and Denka black (5 wt. %) were sequentially added and thoroughly ground for 30 mins under room temperature. The slurry was coated on a copper foil by using a doctor blade (˜200 μm), and the coated electrode was then dried in the vacuum oven for 12 h at 80° C. The mass loading of active material (SiO/C) is 1.52±0.12 mg/cm².

Graphite electrodes: 7 wt. % of PFM binder was dissolved in specific amount of chlorobenzene to form a homogeneous and vicious solution. Then, graphite (Hitachi, 90 wt. %) and Denka black (3 wt. %) were sequentially added and thoroughly ground for 30 mins under room temperature. The slurry was coated on a copper foil by using a doctor blade (˜200 μm), and the coated electrode was then dried in the vacuum oven for 12 h at 80° C. The mass loading of active material (graphite) is 3.60±0.35 mg/cm².

Binder electrodes: 70 wt. % of PFM binder was dissolved in specific amount of chlorobenzene to form a homogeneous and vicious solution. Then, Denka black (30 wt. %) was added and thoroughly ground for 30 mins under room temperature. The slurry was coated on a copper foil by using a doctor blade (˜200 μm), and the coated electrode was then dried in the vacuum oven for 12 h at 80° C. The mass loading of PFM binder is 0.77±0.09 mg/cm².

The SiO/C (or graphite, binder) electrodes with the PFM binder was heated to a certain temperature (e.g. 500° C. for 15 mins with a ramp rate of 5° C./min) in a tube furnace under ultrapure argon flow to obtain the final electrodes. Experimentally, a mass retention of ˜95% for the SiO/C electrodes (˜97% for the graphite electrodes) was observed due to thermal decomposition of the PFM binder.

The above discussed electrode formation and processing can be adopted broadly. The storage materials can be nano- or micron-sized Si particles, Sn particles, graphite, Al, mixed sized and materials particles. The electrode comprises one or more particles and PFM binder. The PFM content can range from 99.9% to 0.1%. Besides PFM and active materials, conductive ceramic materials can be added, such as LPSCl or LLZO particles to aid the ion conductivity. The higher PFM polymer content aids to minimize electrode porosity but helping adhesion and charge transport. The electrode heating processing can range from 25 to 1000° C., the duration can range from 1 section to 10 hours.

The Li-ion diffusion coefficient (t⁺) measurement in the PFM thermal processed film. Potentiostatic intermittent titration technique (PITT) measurements were used to study the diffusion coefficient for PFM (and its derivatives) coating on copper foil by voltage scanning from open-circuit voltage to 0.01 V at a rate of 1 mV/min. Li chip was used as the counter and reference electrode and 1.2M LiPF₆ in EC-EMC was used as the electrolyte. The thickness for both PFM and HOS-PFM are 3.0 μm (L), dln(i)/dt is the slope of ln(current) vs. time (t) curve. The diffusion coefficient in bulk polymers was calculated based on eq. 1.

$${D}_{Li} = \frac{d ln ( i )}{dt} \times \frac{4 {L}^{2}}{{π}^{2}} . \qquad ( eq . 1 )$$

The Li-ion solid state transport experiments in the PFM thermal processed film.

Na/HOS-PFM/Cu doping experiments: PFM in chlorobenzene (2.5 wt. %) was coated on 25 μm Au foil. The mass of polymer coating layer was 12 mg, and the thickness by calculation is 4.8 μm. The bilayer sample was thermal treated at 500° C. under argon atmosphere. A trilayer device was fabricated as shown below. Na chip was used as a counter electrode placed on the top, a separator with a hole in the center was applied between polymer-Au and Na. The trilayer device was placed under pressure of 1.2 ton for 80 min to ensure a good contact with all components and the potential was monitored. The open circuit voltage (OCV) of the trilayer device dropped to about 60-80 μV in few minutes (the initial reading indicates it was open circuit), indicating that the sodium ions are transported through the 4.8 μm distance, and this polymer was entirely doped by sodium ion to be conductive.

Li/HOS-PFM/Au alloying experiments: PFM in chlorobenzene (2.5 wt. %) was coated on 25 μm Au foil. The mass of polymer coating layer was 12 mg, and the thickness by calculation is 4.8 μm. The bilayer sample was thermal treated at 500° C. under argon atmosphere. A trilayer device was fabricated as shown below. Li chip was used as a counter electrode placed on the top, a separator with a hole in the center was applied between polymer-Au and Li. The trilayer device was placed under pressure of 1.2 ton for 80 min to ensure a good contact with all components and the potential was monitored. The open circuit voltage (OCV) of the trilayer device dropped to about 50 μV in few minutes. Visually, the surface lithium looks absorbed into the polymer-Au and the area contacted with lithium turned black. The sample was sealed in PET pouch for XRD. Diffraction from the polymer surface shows some new peaks from Au—Li alloy, indicating that this polymer can transport Li in solid state.

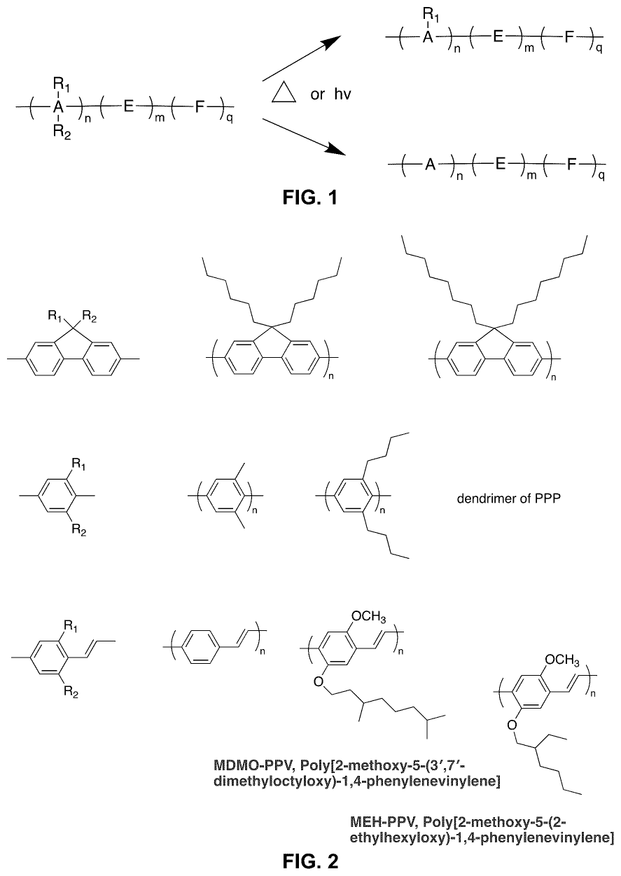

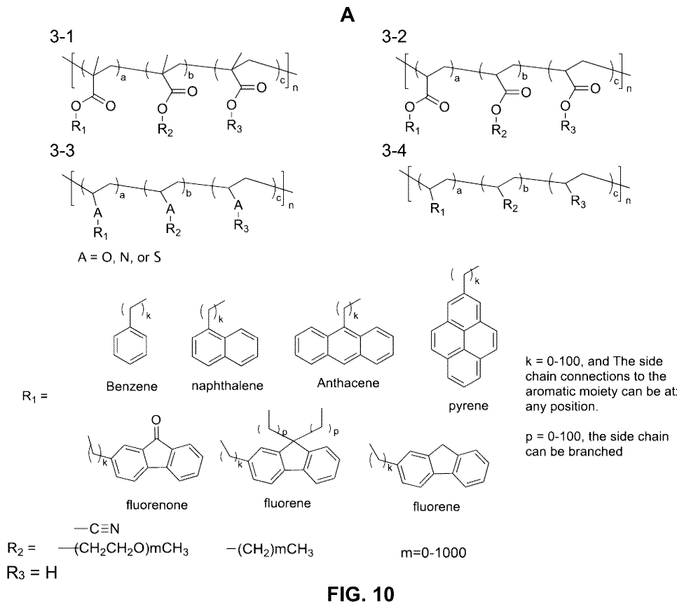

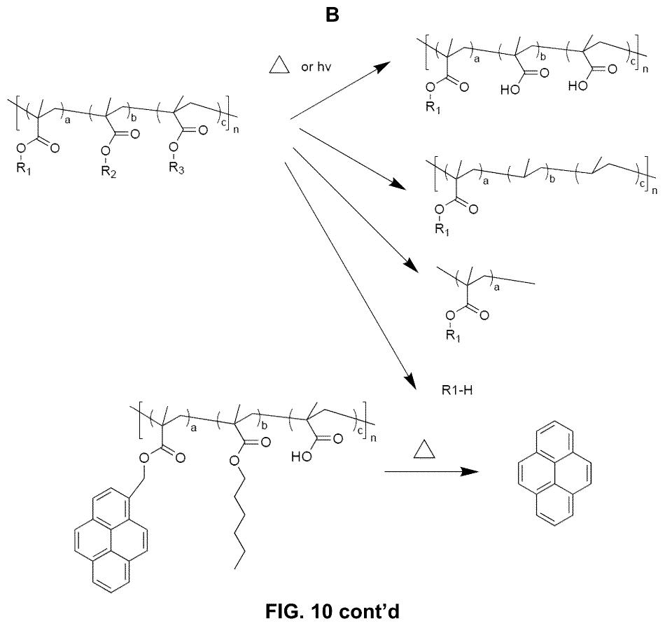

Generic description of the class polymer structures that can be processed to dual charge (ion and electron) conductors. As PFM and the process to HOS-PFM, a class of conductive polymer materials with side chain structures as 1^{st}-4^{th} generic structures (FIGS. 1, 5, 9 and 10) suitable as dual charge (ion and electron) conductor is disclosed. It can also be used as electrode binders for Si, Sn and other alloy based composite electrodes. It also functions with carbon and graphite-based materials. This class of functional conductive polymer materials provides strong adhesion to the Si, Sn and carbon materials and Cu current collectors as an effective electrode binder. Thermal treatment of the polymer materials leads to the loss of the side chains to provide permanent and superb pathways in the polymer films for lithium ion transport. When the polymers are applied on surface of Si or graphite, the polymers in touch with the active materials (Si, Sn and Carbon) surface transforms into passivation layer during the electrochemical process to provide very strong passivation to the active materials surface. The ion pathway in the polymer binder due to the thermal decomposition of side chains provides ion transport. Unlike the usage of only a few percent of conventional binders, it is preferentially to use this functional binder to cover the entire active materials particles surface to provide both strong adhesion and surface protection. In some cases, the binder can fill the entire pores of the electrode. The results based on a 500° C. thermal treated Si composite electrode are excellent both in capacity retention and coulombic efficiency. We also anticipate this class of electrode binders works for the anode for Na ion battery, Mg ion battery, and for solid-state batteries.

Polymers that can be processed in environmentally benign solvents. (1) This synthetic polymer has a rigid backbone for electron conduction and mechanical robustness, triethylene oxide side chains for better solubility and ion transport, and methyl ester for adhesion. (2) This polymer can be thermally processed to cleave side-chains and form well-defined morphology for better charge transport. Processing temperature can be lower (about 300-400° C.) compared to our previous reported PFM type of polymers (about 500° C.). (3) Unlike other conductive we proposed earlier, this polymer can be processed with a variety of non-toxic organic solvents including NMP, DMSO, ethanol, water, or the mixtures of the said solvents. (4) This polymer can support stable cycling of micro-sized silicon with high areal loading in conventional cell design and carbonate electrolytes.

Synthesis of 2,7-dibromo-9,9(di(oxy-2,5,8-trioxadecane))-fluorene: 2,7-Dibromofluorene (1.0 g, 3.09 mmol) was dissolved in dried THF solution (16 mL, 0.154 mol/L) in a 200 mL round bottomed 3 neck bottle. Sodium hydride (0.3 g, 12.5 mmol) was added slowly to the stirred THF solution at room temperature under nitrogen atmosphere. (sodium hydride usually obtain as dispersion in mineral oil, 60 wt %, ˜0.5 g) The reaction mixture was refluxed at 85° C. for 4 hours. 2-(2-(2-Methoxyethoxy)ethoxy) ethyl-4-methylbenzenesulfonate (2.36 g, 7.4 mmol) in 3 mL of dry THF was added dropwise to the refluxed solution and allow the mixture to reflux overnight. The mixture to room temperature and pour the mixture into distilled water to quench unreacted sodium hydride. The mixture was extracted with dichloromethane three times. The organic layer was combined, washed with saturated NaCl solution and distilled water (1×100 mL) and dried with MgSO₄. The solvent was removed by reduced pressure rotary evaporation. The crude product was purified by column chromatography ethyl acetate/petroleum ether=1/1 and the structure was confirmed with NMR.

Synthesis of poly(9,9-di(oxy-2,5,8-trioxadecane)fluorene-co-methylbenzoic ester) (PEM), and poly(9,9-di(oxy-2,5,8-trioxadecane)fluorene-co-(9,9-dioctylfluorene)) (PEF): A mixture of 2,7-dibromo-9,9(di(oxy-2,5,8-trioxadecane))-fluorene (1.48 mmol), 9,9-dioctylfluorene-2,7-diboronic acid bis(1,3-propanediol) ester (for PEF, 0.826 g, 1.48 mmol), (or methyl-2,5-dibromobenzoate for PEM, 1.48 mmol), (PPh₃)₄Pd(0) (0.085 g, 0.074 mmol) and several drops of Aliquat 336 in a mixture of toluene (10 mL), THF (2 mL) and 2 M Na₂CO₃ (5 mL) solution was refluxed with vigorous stirring for 72 h under an argon atmosphere. The copolymer was precipitated twice from cold methanol and dried in vacuum.

Electrode fabrication and thermal processing: 15 wt. % of PEF or PEM binder was dissolved in specific amount of chlorobenzene to form a homogeneous and vicious solution. Then, SiO/C (Shinetsu, 60 wt. %), graphite (Hitachi, 20 wt. %) and Denka black (5 wt. %) were sequentially added and thoroughly ground for 30 mins under room temperature. The slurry was coated on a copper foil by using a doctor blade (˜200 μm), and the coated electrode was then dried in the vacuum oven for 12 h at 80° C. The electrode was further transferred to a tube finance for thermal processing at a temperature of 400° C. to cleave the oligo-EO side chains (500° C. for alkyl chains) under continuous argon-flow. The thermal processed electrodes were further punched into round disks for coin cell assembly. See FIG. 17.

The present invention provides for a conductive polymer with simple primary building blocks that can be thermally processed to develop hierarchically ordered structures (HOS) with well-defined nanocrystalline morphologies. This approach to constructing permanent HOS in conductive polymers leads to substantial enhancement of charge transport properties and mechanical robustness, which are critical for practical lithium-ion batteries, Herein are examples demonstrating that conductive polymers with HOS enable exceptional cycling performance of full cells with high-loading micron-size SiOₓ-based anodes, delivering areal capacities of more than 3.0 mAh cm⁻² over 300 cycles and average Coulombic efficiency of >99.95%.

While the present invention has been described with reference to the specific embodiments thereof, it should be understood by those skilled in the art that various changes may be made and equivalents may be substituted without departing from the true spirit and scope of the invention. In addition, many modifications may be made to adapt a particular situation, material, composition of matter, process, process step or steps, to the objective, spirit and scope of the present invention. All such modifications are intended to be within the scope of the claims appended hereto.

What is claimed is:

1. A composition comprising: a solvent, optionally one or more active material and/or additive particles, and a conductive polymer having the following chemical structure: 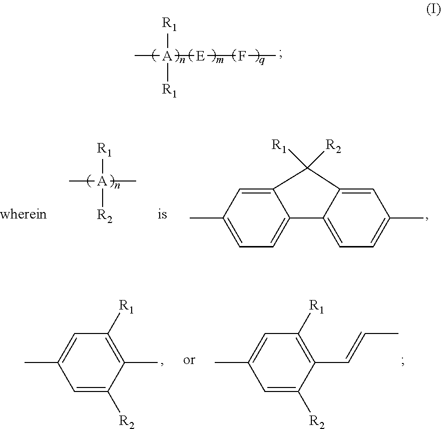
E and F are each independently 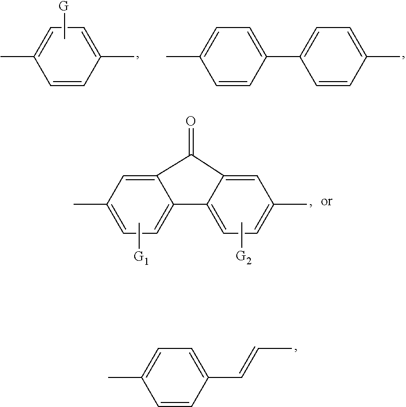
G, G₁, and G₂ are independently are —H, —F, —COOCH₃, —COOH, —SO₃CH₃; n+m+q=1, and representing the relative abundance in the polymer chain; n, m, and q can be any number between 0-1; R₁ and R₂ are an alkyl chain or oligo ethyleoxide chain or alkyloxide chain of any length between 1-10000 carbon atoms; and, R₁ and R₂ can be hydroxide terminated or carboxylic acid or carboxylate salt terminated;
(b) -Qₙ-Q′ₘ- (II); wherein n is between 1 and 100M Dalton; R₁ and/or R₂ are independently an alkyl chain or oligo ethyleoxide chain or alkyloxide chain of any length between 1-10000 carbon atoms; and R₁ and/or R₂ can be hydroxide terminated or carboxylic acid or carboxylate salt terminated;
(c) 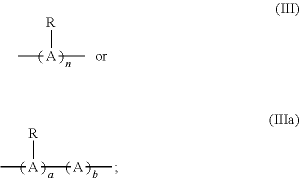
wherein R is an alkyl chain or oligo ethyleoxide chain or alkyloxide chain of any length between 1-10000 carbon atoms; 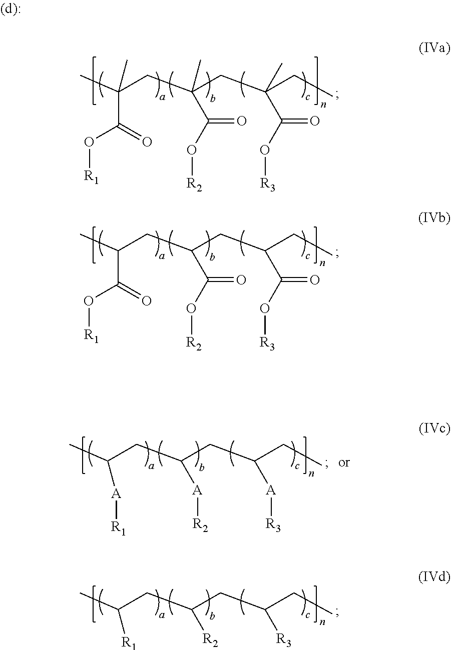
wherein A is O, N, or S; R₁ is 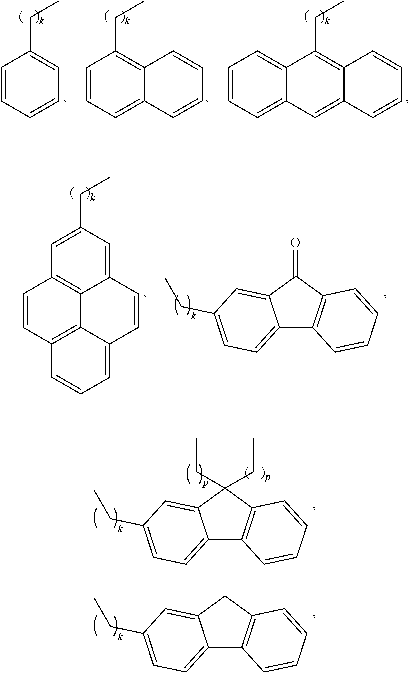
or —C≡N; R₂ is —(CH₂CH₂O)ₘCH₃, or —(CH₂)ₘCH₃; R₃ is H; wherein m is 0 to 1000; wherein k is 0 to 100, the side chain connection to the aromatic moiety can be at any position, p is 0 to 100, the side chain can be branched; m is 1 to 100; and a+b+c=1, and representing the relative abundance in the polymer chain; a, b, and c can be any number between 0-1;
(e) 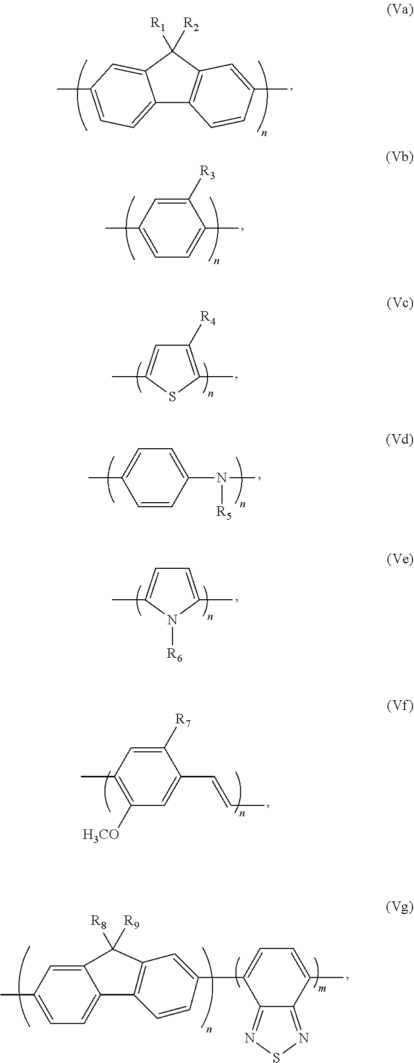 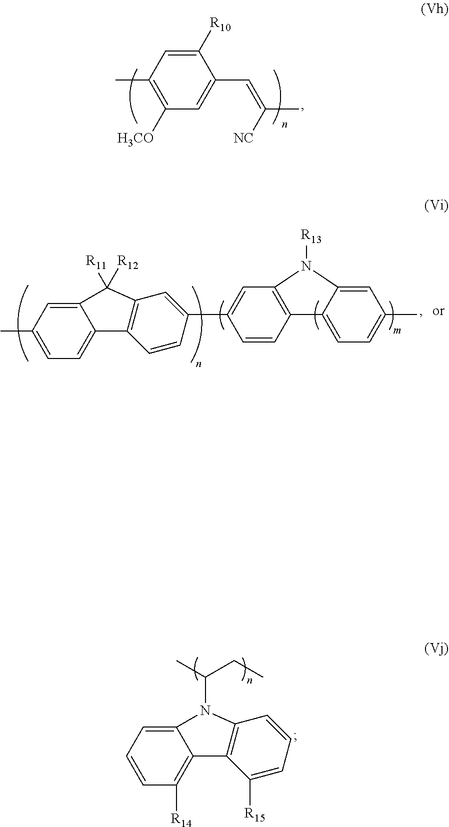
wherein R₁-R₁₅ are selected from the group consisting of an oligoether group, an alkyl chain having a tertiary amine and an associated counter ion, and an alkyl chain having an SO₃ group and an associated counter ion; wherein said oligoether group terminates with a methyl group or hydroxyl group; and wherein n is between 2 and 1000;
or a mixture thereof.

2. The composition of claim 1, wherein the composition is a slurry.

3. The composition of claim 1, wherein conductive polymer has the following chemical structure: 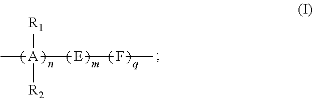
n+m+q=1, and representing the relative abundance in the polymer chain; n, m, and q can be any number between 0-1; R₁ and R₂ are an alkyl chain or oligo ethyleoxide chain or alkyloxide chain of any length between 1-10000 carbon atoms; and, R₁ and R₂ can be hydroxide terminated or carboxylic acid or carboxylate salt terminated.

4. The composition of claim 3, wherein chemical structure (I) has the following chemical structure:

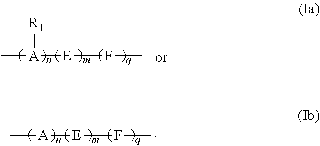

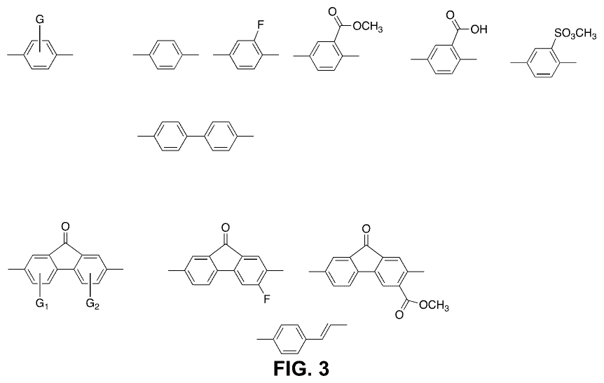

5. The composition of claim 3, wherein the 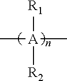
segment(s) is one of the chemical structures described in FIG. 2.

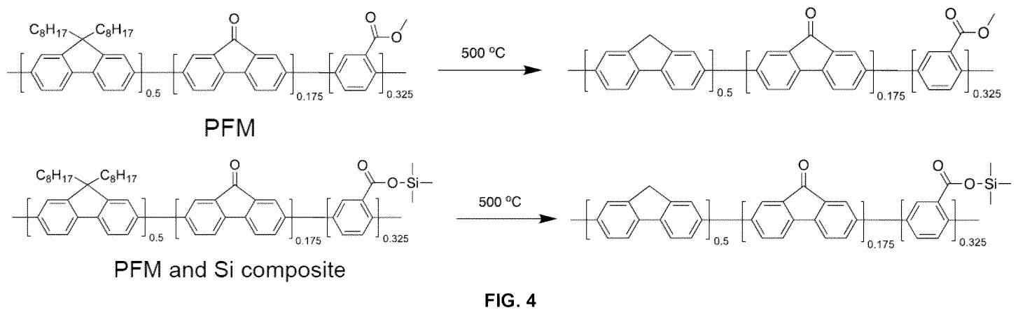

6. The composition of claim 3, wherein the 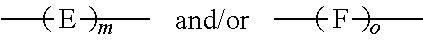
segment(s) are independently one of the chemical structures described in FIG. 3.

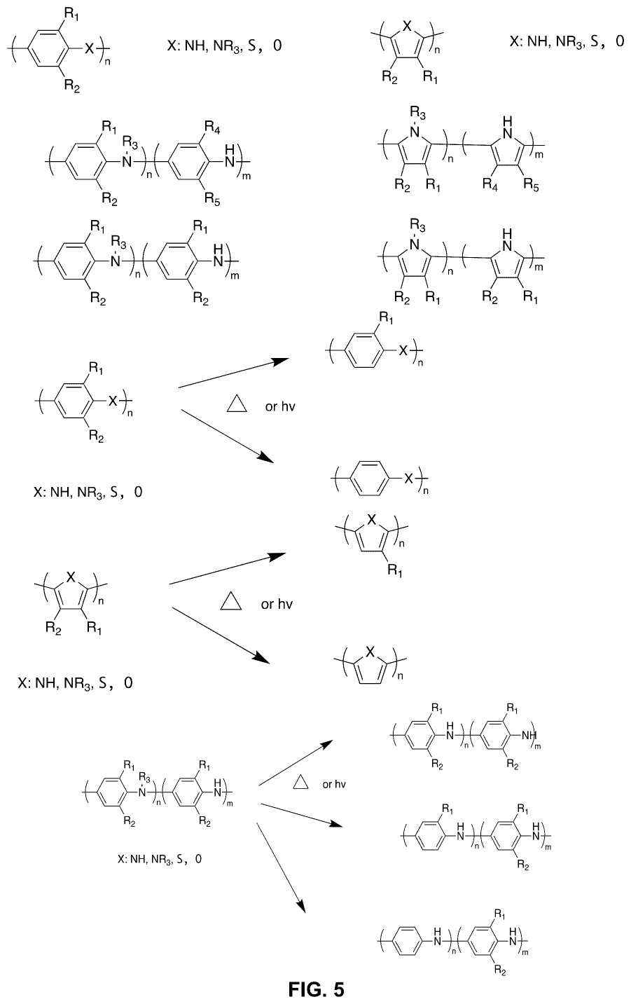

7. The composition of claim 3, wherein the chemical structure (I) is described in FIG. 4.

8. The composition of claim 1, wherein conductive polymer has the following chemical structure: -Qₙ-Q′ₘ- (II); wherein n is between 1 and 100M Dalton; R₁ and/or R₂ are independently an alkyl chain or oligo ethyleoxide chain or alkyloxide chain of any length between 1-10000 carbon atoms; and R₁ and/or R₂ can be hydroxide terminated or carboxylic acid or carboxylate salt terminated.

9. The composition of claim 8, wherein -Q′ₘ- is a covalent bond.

10. The composition of claim 8, wherein n+m=1, and representing the relative abundance in the polymer chain; n and m can be any number between 0-1.

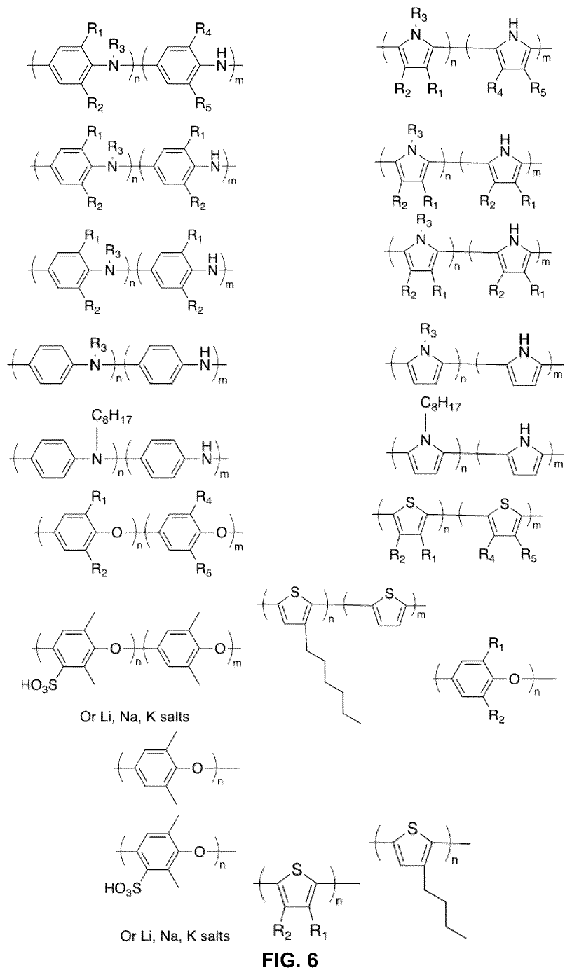

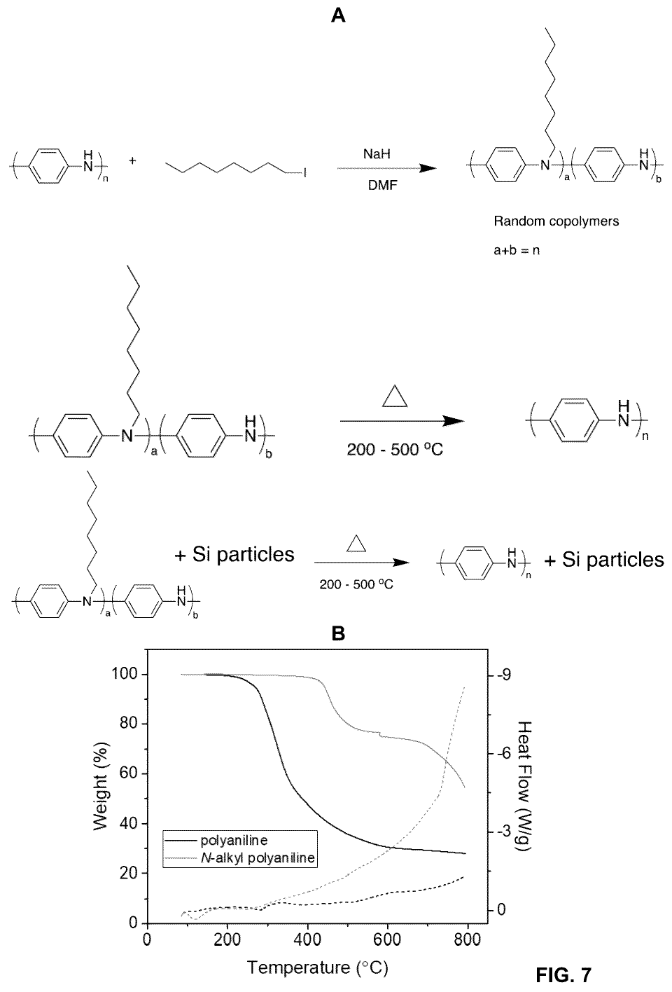

11. The composition of claim 8, wherein chemical structure (II) comprises one of chemical structures described in FIG. 5 or FIG. 6.

12. The composition of claim 1, wherein conductive polymer has the following chemical structure: 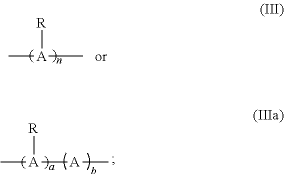
wherein R is an alkyl chain or oligo ethyleoxide chain or alkyloxide chain of any length between 1-10000 carbon atoms.

13. The composition of claim 8, wherein R is hydroxide terminated or carboxylic acid or carboxylate salt terminated.

14. The composition of claim 1, wherein the conductive polymer has the following chemical structure: 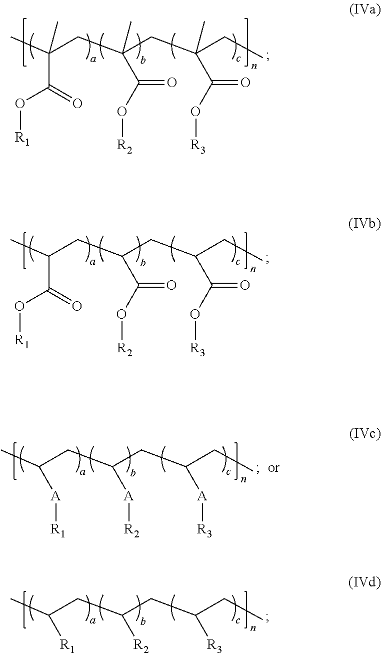
wherein A is O, N, or S; R₁ is 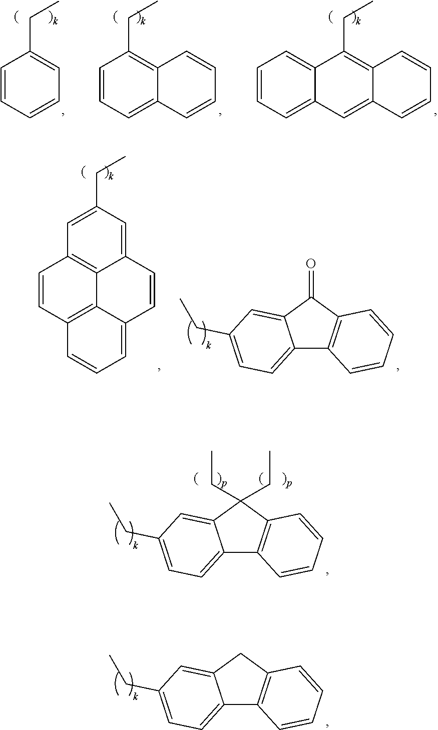
or —C≡N; R₂ is —(CH₂CH₂O)ₘCH₃, or —(CH₂)ₘCH₃; R₃ is H; wherein m is 0 to 1000; wherein k is 0 to 100, the side chain connection to the aromatic moiety can be at any position, p is 0 to 100, the side chain can be branched; m is 1 to 100; and a+b+c=1, and representing the relative abundance in the polymer chain; a, b, and c can be any number between 0-1.

15. The composition of claim 14, wherein R₁ is benzene, naphthalene, anthracene, pyrene, fluorenone, or fluorene, or nitrile.

16. The composition of claim 14, wherein k is 1 to 100.

17. The composition of claim 14, wherein p is 1 to 100.

18. The composition of claim 1, wherein the conductive polymer has the following chemical structure: 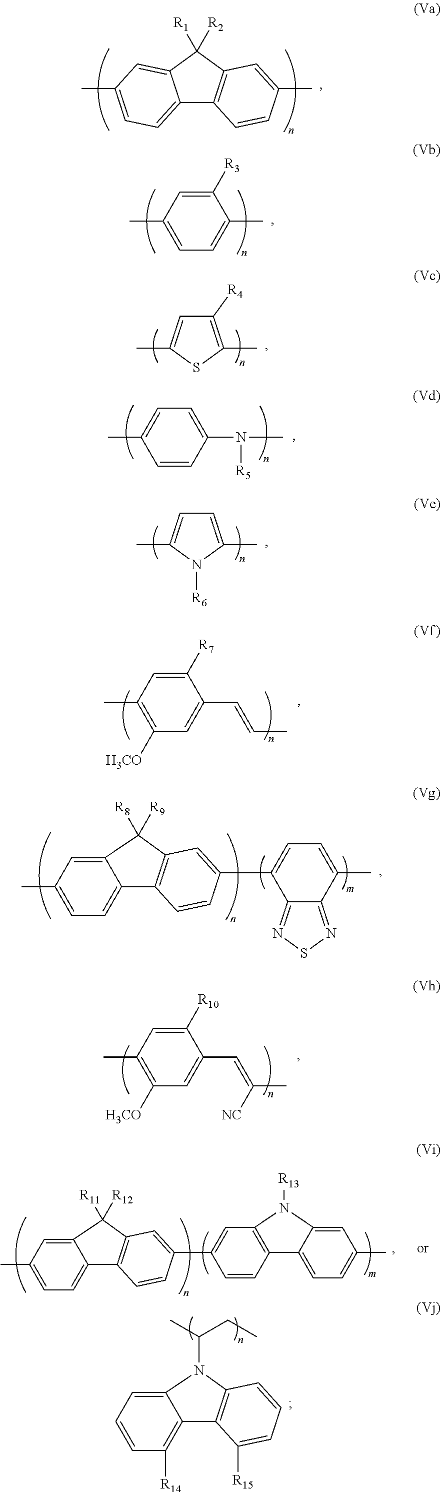
wherein R₁-R₁₅ are selected from the group consisting of an oligoether group, an alkyl chain having a tertiary amine and an associated counter ion, and an alkyl chain having an SO₃ group and an associated counter ion; wherein said oligoether group terminates with a methyl group or hydroxyl group; and wherein n is between 2 and 1000.

19. The composition of claim 18, wherein the conductive polymer has the following chemical structure:

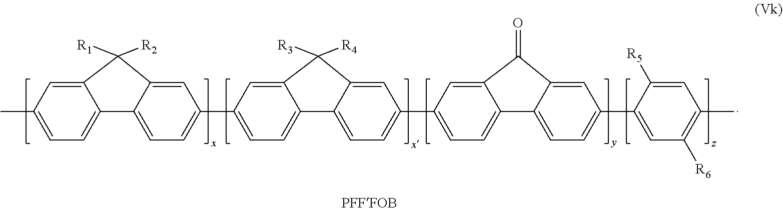

20. The composition of claim 1, wherein the conductive polymer is poly(2,7-9,9-(di(oxy-2,5,8-trioxadecane))fluorene) (“PFO”).

21. A device comprising a current collector applied or coated with the composition of claim 1.

22. The device of claim 21, wherein the composition is dried on the current collector.

23. The device of claim 22, wherein the dried composition is a film.

24. A method to convert a conductive polymer into a final form, the method comprising: (a) providing a device of the present invention comprising a current collector applied or coated with the composition of claim 1; (b) thermally or optically treating the composition such that the conductive polymer is converted into a final form.

25. The method of claim 24, wherein the thermally treating step comprises heating the composition.

26. The method of claim 25, wherein the thermally treating step comprises heating the composition to a temperature ranging from about 100° C. to about 1000° C.

27. The method of claim 24, wherein the thermally or optically treating step takes place in an oxygen free condition, or a control amount of oxygen condition.

28. The method of claim 24, wherein the optically treating step comprises contacting or shining high-energy visible light on the composition.

29. The method of claim 24, wherein the thermally or optically treating step results in the separating or removing of one or more R group, or side chain/functional group, from the conductive polymer.
